(19) United States
(12) Patent Application Publication
(10) Pub. No.: US 2011/0114156 A1
(43) Pub. Date: May 19, 2011

(54) PHOTOVOLTAIC MODULES HAVING A BUILT-IN BYPASS DIODE AND METHODS FOR MANUFACTURING PHOTOVOLTAIC MODULES HAVING A BUILT-IN BYPASS DIODE

(75) Inventors: Kevin Coakley, Mountain View, CA (US); Guleid Hussen, Mountain View, CA (US); Jason Stephens, Mountain View, CA (US)

(73) Assignee: THINSILICON CORPORATION, Mountain View, CA (US)

(21) Appl. No.: 12/963,424

(22) Filed: Dec. 8, 2010

Related U.S. Application Data
(63) Continuation-in-part of application No. 12/796,378, filed on Jun. 8, 2010.
(60) Provisional application No. 61/185,770, filed on Jun. 10, 2009.
(60) Provisional application No. 61/221,816, filed on Jun. 30, 2009.
(60) Provisional application No. 61/230,790, filed on Aug. 3, 2009.

(51) Int. Cl. H01L 31/06; H01L 31/18

(52) U.S. Cl. 136/249; 438/73; 257/E31.001

(57) ABSTRACT

A photovoltaic device includes: a substrate; lower and upper electrode layers disposed above the substrate; and a semiconductor layer disposed between the lower and upper electrode layers, the semiconductor layer absorbing incident light to excite electrons from the semiconductor layer, wherein the semiconductor layer includes a built-in bypass diode extending between and coupled with the lower and upper electrode layers, the bypass diode permitting electric current to flow through the bypass diode when a reverse bias is applied across the lower and upper electrode layers.

### CROSS-REFERENCE TO RELATED APPLICATIONS

This application is a continuation-in-part of co-pending U.S. application Ser. No. 12/796,378, entitled “Photovoltaic Modules And Methods For Manufacturing Photovoltaic Modules Having Tandem Semiconductor Layer Stacks,” and filed on Jun. 8, 2010 (the “'378 Application”). The '378 Application is a nonprovisional patent application of, and claims priority benefit from, U.S. Provisional Patent Application Ser. No. 61/185,770, entitled “Photovoltaic Devices Having Tandem Semiconductor Layer Stacks” (the “'770 Application”), and filed on Jun. 10, 2009; U.S. Provisional Patent Application Ser. No. 61/221,816, entitled “Photovoltaic Devices Having Multiple Semiconductor Layer Stacks” (the “'816 Application”), and filed on Jun. 30, 2009; and U.S. Provisional Patent Application Ser. No. 61/230,790, entitled “Photovoltaic Devices Having Multiple Semiconductor Layer Stacks” (the “'790 Application”), and filed on Aug. 3, 2009. The entire disclosure of the above listed applications (the '378, '770, '816, and '790 Applications) are incorporated by reference herein in their entirety.

### BACKGROUND OF THE INVENTION

The subject matter described herein relates to photovoltaic devices. Some known photovoltaic devices include thin film solar modules having active portions of thin films of silicon. Light that is incident onto the modules passes into the active silicon films. If the light is absorbed by the silicon films, the light may generate electrons and holes in the silicon. The electrons and holes are used to create an electric potential and/or an electric current that may be drawn from the modules and applied to an external electric load.

Photons in the light excite electrons in the silicon films and cause the electrons to separate from atoms in the silicon films. In order for the photons to excite the electrons and cause the electrons to separate from the atoms in the films, the photons must have an energy that exceeds the energy band gap in the silicon films. The energy of the photons is related to the wavelengths of light that is incident on the films. Therefore, light is absorbed by the silicon films based on the energy band gap of the films and the wavelengths of the light.

Some known photovoltaic devices include tandem layer stacks that include two or more sets of silicon films deposited on top of one another and between a lower electrode and an upper electrode. The different sets of films may have different energy band gaps. Providing different sets of films with different band gaps may increase the efficiency of the devices as more wavelengths of incident light can be absorbed by the devices. For example, a first set of films may have a greater energy band gap than a second set of films. Some of the light having wavelengths associated with an energy that exceeds the energy band gap of the first set of films is absorbed by the first set of films to create electron-hole pairs. Some of the light having wavelengths associated with energy that does not exceed the energy band gap of the first set of films passes through the first set of films without creating electron-hole pairs. At least a portion of this light that passes through the first set of films may be absorbed by the second set of films if the second set of films has a lower energy band gap.

In order to provide different sets of films with different energy band gaps, the silicon films may be alloyed with germanium to change the band gap of the films. But, alloying the films with germanium tends to reduce the deposition rate that can be used in manufacturing. Furthermore, silicon films alloyed with germanium tend to be more prone to light-induced degradation than those with no germanium. Additionally, germane, the source gas used to deposit silicon-germanium alloy, is costly and hazardous.

As an alternative to alloying silicon films with germanium, the energy band gap of silicon films in a photovoltaic device may be reduced by depositing the silicon films as microcrystalline silicon films instead of amorphous silicon films. Amorphous silicon films typically have larger energy band gaps than silicon films that are deposited in a microcrystalline state. Some known photovoltaic devices include semiconductor layer stacks having amorphous silicon films stacked in series with a microcrystalline silicon films. In such devices, the amorphous silicon films are deposited in a relatively small thickness to reduce carrier transport-related losses in the junction. For example, the amorphous silicon films may be deposited with a small thickness to reduce the amount of electrons and holes that are excited from silicon atoms by incident light and recombine with other silicon atoms or other electrons and holes before reaching the top or bottom electrodes. The electrons and holes that do not reach the electrodes do not contribute to the voltage or current created by the photovoltaic device. But, as the thickness of the amorphous silicon junction is reduced, less light is absorbed by the amorphous silicon junction and the flow of photocurrent in the silicon films is reduced. As a result, the efficiency of the photovoltaic device in converting incident light into electric current can be limited by the amorphous silicon junction in the device stack.

In some photovoltaic devices having relatively thin amorphous silicon films, the surface area of photovoltaic cells in the device that have the active amorphous silicon films may be increased relative to inactive areas of the cells. The active areas include the silicon films that convert incident light into electricity while non-active or inactive areas include portions of the cells where the silicon film is not present or that do not convert incident light into electricity. The electrical power generated by photovoltaic devices may be increased by increasing the active areas of the photovoltaic cells in the device relative to the inactive areas in the device. For example, increasing the width of the cells in a monolithically-integrated thin film photovoltaic module having active amorphous silicon films increases the fraction or percentage of active photovoltaic material in the module that is exposed to sunlight. As the fraction of active photovoltaic material increases, the total photocurrent generated by the device may increase.

Increasing the width of the cells also increases the size or area of light-transmissive electrodes of the device. The light-transmissive electrodes are the electrodes that conduct electrons or holes created in the cells to create the voltage or current of the device. As the size or area of the light-transmissive electrodes increases, the electrical resistance (R) of the light-transmissive electrodes also increases. The electric current (I) that passes through the light-transmissive electrodes also may increase. As the current passing through the light-transmissive electrodes and the resistance of the light-transmissive electrodes increase, energy losses, such as I²R losses, in the photovoltaic device increase. As the energy losses increase, the photovoltaic device becomes less efficient and less power is generated by the device. Therefore, in monolithically-integrated thin film photovoltaic devices, there exists a trade-off between the fraction of active photovoltaic material in the devices and the energy losses incurred in the transparent conducting electrodes of the devices.

In some known photovoltaic devices, the photovoltaic cells are electrically coupled in series with each other. The series connection of the photovoltaic cells may risk damage to the device if one of the cells becomes reverse biased. For example, some known photovoltaic cells have become damaged or destroyed when one of several serially connected cells is shaded from incident light (e.g., “shaded cell”) while the adjacent cells are exposed to the light (e.g., “illuminated cells”). The illuminated cells generate electric current on opposite sides of the shaded cell and cause a voltage potential across the shaded cell. If the voltage potential is relatively large, the shaded cell may heat up and become damaged. For example, the shaded cell may ignite or combust and cause failure or destruction of the device.

Some known photovoltaic devices include bypass diodes that are joined to the cells. The bypass diodes permit electric current to bypass a shaded cell. For example, the voltage potential that would otherwise build up on opposite sides of a shaded cell is passed through the bypass diode between the illuminated cells and bypasses the shaded cell. These bypass diodes may be separately formed from the cells and are then coupled with the cells after the cells are formed. For example, the bypass diodes may be joined to the cells below the cells and/or substrate on which the cells are formed. Providing these bypass diodes requires additional equipment, processing steps, and/or components. For example, additional manufacturing equipment and/or processing may be required to form and/or couple the bypass diodes. Additional components may be added to the known cells to provide the bypass diode. The addition of more components to the cells may decrease the efficiency of the cells and/or provide increased failure rates of the cells.

A need exists for photovoltaic devices having increased efficiency in converting incident light into electric current and/or with decreased energy losses.

### BRIEF DESCRIPTION OF THE INVENTION

In one embodiment, a photovoltaic device includes: a substrate; lower and upper electrode layers disposed above the substrate; and a semiconductor layer disposed between the lower and upper electrode layers, the semiconductor layer absorbing incident light to excite electrons from the semiconductor layer, wherein the semiconductor layer includes a built-in bypass diode extending between and coupled with the lower and upper electrode layers, the bypass diode permitting electric current to flow through the bypass diode when a reverse bias is applied across the lower and upper electrode layers.

In another embodiment, a method for manufacturing a photovoltaic device includes: depositing a lower electrode layer above a substrate, a semiconductor layer above the lower electrode layer, and an upper electrode layer above the semiconductor layer, the semiconductor layer configured to absorb incident light to excite electrons from the semiconductor layer; and increasing at least one of a crystallinity or a diffusion of dopants in the semiconductor layer between the lower electrode layer and the upper electrode layer to form a built-in bypass diode, the bypass diode configured to permit electric current to flow through the bypass diode when a reverse bias is applied across the lower and upper electrode layers.

In another embodiment, a photovoltaic device includes: a substrate; and a plurality of electrically coupled photovoltaic cells disposed above the substrate in a direction that incident light is received by the photovoltaic cells, the photovoltaic cells generating electric current based on the light that is received by the photovoltaic cells, each of the photovoltaic cells including: lower and upper electrode layers disposed above the substrate; and a semiconductor layer disposed between the lower and upper electrode layers, the semiconductor layer absorbing the light to excite electrons from the semiconductor layer, wherein the semiconductor layer of at least one of the photovoltaic cells includes a built-in bypass diode extending between and coupled with the lower and upper electrode layers of the at least one of the photovoltaic cells, the bypass diode permitting the electric current to flow between neighboring ones of the photovoltaic cells through the bypass diode when the at least one of the photovoltaic cells is reverse biased.

### BRIEF DESCRIPTION OF THE DRAWINGS

FIG. 1 is a schematic view of a photovoltaic cell in accordance with one embodiment.

FIG. 2 schematically illustrates structures in a template layer shown in FIG. 1 in accordance with one embodiment.

FIG. 3 schematically illustrates structures in the template layer shown in FIG. 1 in accordance with another embodiment.

FIG. 4 schematically illustrates structures in the template layer shown in FIG. 1 in accordance with another embodiment.

FIG. 5 is a schematic diagram of a photovoltaic device and a magnified view of the device according to one embodiment.

FIG. 6 is a flowchart of a process for manufacturing a photovoltaic device in accordance with one embodiment.

FIG. 7 is a schematic diagram of a photovoltaic device and a magnified view of the device according to another embodiment.

FIG. 8 is a perspective view of a scribing system in accordance with one embodiment.

FIG. 9 is a perspective view of the scribing system shown in FIG. 8 in accordance with one embodiment.

FIG. 10 is a cross-sectional view of the photovoltaic device along line 10-10 in FIG. 9 in accordance with one embodiment.

FIG. 11 illustrates an I-V curve of a bypass diode shown in FIG. 10 in accordance with one embodiment.

FIG. 12 illustrates another I-V curve of the bypass diode shown in FIG. 10 in accordance with one embodiment.

FIG. 13 is a flowchart of a process for manufacturing a photovoltaic device in accordance with one embodiment.

The foregoing summary, as well as the following detailed description of certain embodiments of the presently described technology, will be better understood when read in conjunction with the appended drawings. For the purpose of illustrating the presently described technology, certain embodiments are shown in the drawings. It should be understood, however, that the presently described technology is not limited to the arrangements and instrumentality shown in the attached drawings. Moreover, it should be understood that the components in the drawings are not to scale and the relative sizes of one component to another should not be construed or interpreted to require such relative sizes.

### DETAILED DESCRIPTION OF THE INVENTION

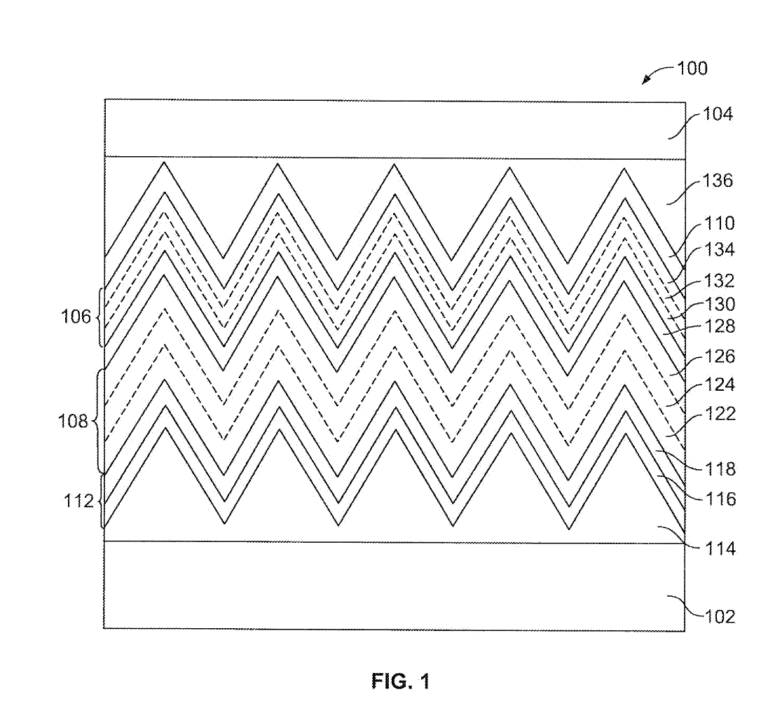

FIG. 1 is a schematic view of a photovoltaic cell 100 in accordance with one embodiment. The cell 100 may be one of several electrically coupled cells 100 in a photovoltaic device, such as a photovoltaic module. The cell 100 includes a substrate 102 and a light transmissive cover layer 104 with upper and lower active silicon layer stacks 106, 108 disposed between upper and lower electrode layers 110, 112, or electrodes 110, 112. The upper and lower electrode layers 110, 112 and the upper and lower layer stacks 106, 108 are located between the substrate 102 and cover layer 104. The cell 100 is a substrate-configuration photovoltaic cell. For example, light that is incident on the cell 100 on the cover layer 104 opposite the substrate 102 passes into and is converted into an electric potential by active silicon layer stacks 106, 108 of the cell 100. The light passes through the cover layer 104 and additional layers and components of the cell 100 to the upper and lower layer stacks 106, 108. The light is absorbed by the upper and lower layer stacks 106, 108.

Photons in the incident light that is absorbed by the upper and lower layer stacks 106, 108 excite electrons in the upper and lower layer stacks 106, 108 and cause the electrons to separate from atoms in the upper and lower layer stacks 106, 108. Complementary positive charges, or holes, are created when the electrons separate from the atoms. The upper and lower layer stacks 106, 108 have different energy band gaps that absorb different portions of the spectrum of wavelengths in the incident light. The electrons drift or diffuse through the upper and lower layer stacks 106, 108 and are collected at one of the upper and lower electrode layers 110, 112. The collection of the electrons at the upper or lower electrode layers 110, 112 generates an electric potential difference in the cell 100. The voltage difference in the cell 100 may be added to the potential difference that is generated in additional cells (not shown). The potential difference generated in a plurality of cells 100 serially coupled with one another may be added together to increase the total potential difference generated by the cells 100. Electric current is generated by the flow of electrons between neighboring cells 100. The current may be drawn from the cells 100 and applied to an external electric load.

The components and layers of the cell 100 are schematically illustrated in FIG. 1, and the shape, orientation and relative sizes of the components and layers are not intended to be limiting. The substrate 102 is located at the bottom of the cell 100. The substrate 102 provides mechanical support to the other layers and components of the cell 100. The substrate 102 includes, or is formed from, a dielectric material, such as a non-conductive material. The substrate 102 may be formed from a dielectric having a relatively low softening point, such as one or more dielectric materials having a softening point below about 750 degrees Celsius. By way of example only, the substrate 102 may be formed from soda-lime float glass, low iron float glass or a glass that includes at least 10 percent by weight of sodium oxide (Na₂O). In another example, the substrate may be formed from another type of glass, such as float glass or borosilicate glass. Alternatively, the substrate 102 is formed from a ceramic, such as silicon nitride (Si₃N₄) or aluminum oxide (alumina, or Al₂O₃). In another embodiment, the substrate 102 is formed from a conductive material, such as a metal. By way of example only, the substrate 102 may be formed from stainless steel, aluminum, or titanium.

The substrate 102 has a thickness that is sufficient to mechanically support the remaining layers of the cell 100 while providing mechanical and thermal stability to the cell 100 during manufacturing and handling of the cell 100. The substrate 102 is at least approximately 0.7 to 5.0 millimeters thick in one embodiment. By way of example only, the substrate 102 may be an approximately 2 millimeter thick layer of float glass. Alternatively, the substrate 102 may be an approximately 1.1 millimeter thick layer of borosilicate glass. In another embodiment, the substrate 102 may be an approximately 3.3 millimeter thick layer of low iron or standard float glass.

A textured template layer 114 may be deposited above the substrate 102. Alternatively, the template layer 114 is not included in the cell 100. The template layer 114 is a layer having a controlled and predetermined three dimensional texture that imparts the texture onto one or more of the layers and components in the cell 100 that are deposited onto or above the template layer 114. In one embodiment, the texture template layer 114 may be deposited and formed in accordance with one of the embodiments described in co-pending U.S. Nonprovisional patent application Ser. No. 12/762,880, entitled “Photovoltaic Cells And Methods To Enhance Light Trapping In Thin Film Silicon,” and filed Apr. 19, 2010 (the “'880 Application”). The entire disclosure of the '880 Application is incorporated by reference herein in its entirety. With respect to the '880 Application, the template layer 114 described herein may be similar to the template layer 136 described in the '880 Application and include an array of one or more of the structures 300, 400, 500 described and illustrated in the '880 Application.

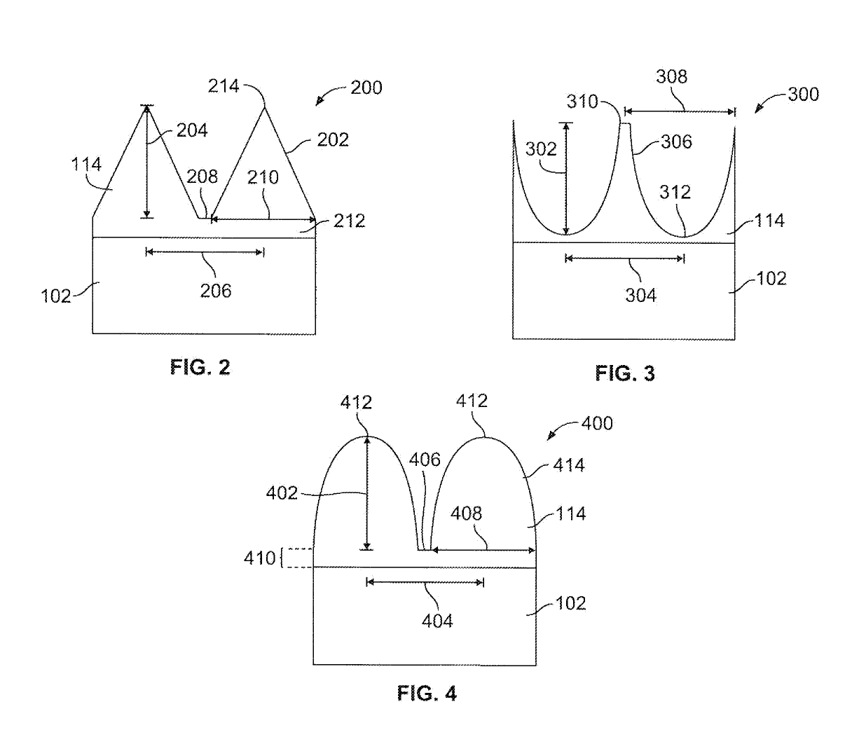

The texture of the template layer 114 in the illustrated embodiment may be determined by the shape and dimensions of one or more structures 200, 300, 400 (shown in FIGS. 2 through 4) of the template layer 114. The template layer 114 is deposited above the substrate 102. For example, the template layer 114 may directly deposited onto the substrate 102.

FIG. 2 schematically illustrates peak structures 200 in the template layer 114 in accordance with one embodiment. The peak structures 200 are created in the template layer 114 to impart a predetermined texture in layers above the template layer 114. The structures 200 are referred to as peak structures 200 as the structures 200 appear as sharp peaks along an upper surface 202 of the template layer 114. The peak structures 200 are defined by one or more parameters, including a peak height (Hpk) 204, a pitch 206, a transitional shape 208, and a base width (Wb) 210. As shown in FIG. 2, the peak structures 200 are formed as shapes that decrease in width as the distance from the substrate 102 increases. For example, the peak structures 200 decrease in size from bases 212 located at or near the substrate 102 to several peaks 214. The peak structures 200 are represented as triangles in the two dimensional view of FIG. 2, but alternatively may have a pyramidal or conical shape in three dimensions.

The peak height (Hpk) 204 represents the average or median distance of the peaks 214 from the transitional shapes 208 between the peak structures 200. For example, the template layer 114 may be deposited as an approximately flat layer up to the bases 212 of the peaks 214, or to the area of the transitional shape 208. The template layer 114 may continue to be deposited in order to form the peaks 214. The distance between the bases 212 or transitional shape 208 to the peaks 214 may be the peak height (Hpk) 204.

The pitch 206 represents the average or median distance between the peaks 214 of the peak structures 200. The pitch 206 may be approximately the same in two or more directions. For example, the pitch 206 may be the same in two perpendicular directions that extend parallel to the substrate 102. In another embodiment, the pitch 206 may differ along different directions. Alternatively, the pitch 206 may represent the average or median distance between other similar points on adjacent peak structures 200. The transitional shape 208 is the general shape of the upper surface 202 of the template layer 114 between the peak structures 200. As shown in the illustrated embodiment, the transitional shape 208 can take the form of a flat “facet.” Alternatively, the flat facet shape may be a cone or pyramid when viewed in three dimensions. The base width (Wb) 210 is the average or median distance across the peak structures 200 at an interface between the peak structures 200 and the base 212 of the template layer 114. The base width (Wb) 210 may be approximately the same in two or more directions. For example, the base width (Wb) 210 may be the same in two perpendicular directions that extend parallel to the substrate 102. Alternatively, the base width (Wb) 210 may differ along different directions.

FIG. 3 illustrates valley structures 300 of the template layer 114 in accordance with one embodiment. The shapes of the valley structures 300 differ from the shapes of the peak structures 200 shown in FIG. 2 but may be defined by the one or more of the parameters described above in connection with FIG. 2. For example, the valley structures 300 may be defined by a peak height (Hpk) 302, a pitch 304, a transitional shape 306, and a base width (Wb) 308. The valley structures 300 are formed as recesses or cavities that extend into the template layer 114 from an upper surface 310 of the valley structures 300. The valley structures 300 are shown as having a parabolic shape in the two dimensional view of FIG. 3, but may have conical, pyramidal, or paraboloid shapes in three dimensions. In operation, the valley structures 300 may vary slightly from the shape of an ideal parabola.

In general, the valley structures 300 include cavities that extend down into the template layer 114 from the upper surface 310 and toward the substrate 102. The valley structures 300 extend down to low points 312, or nadirs, of the template layer 114 that are located between the transition shapes 306. The peak height (Hpk) 302 represents the average or median distance between the upper surface 310 and the low points 312. The pitch 304 represents the average or median distance between the same or common points of the valley structures 300. For example, the pitch 304 may be the distance between the midpoints of the transition shapes 306 that extend between the valley structures 300. The pitch 304 may be approximately the same in two or more directions. For example, the pitch 304 may be the same in two perpendicular directions that extend parallel to the substrate 102. In another embodiment, the pitch 304 may differ along different directions. Alternatively, the pitch 304 may represent the distance between the low points 312 of the valley structures 300. Alternatively, the pitch 304 may represent the average or median distance between other similar points on adjacent valley structures 300.

The transitional shape 306 is the general shape of the upper surface 310 between the valley structures 300. As shown in the illustrated embodiment, the transitional shape 306 can take the form of a flat “facet.” Alternatively, the flat facet shape may be a cone or pyramid when viewed in three dimensions. The base width (Wb) 308 represents the average or median distance between the low points 312 of adjacent valley structures 300. Alternatively, the base width (Wb) 308 may represent the distance between the midpoints of the transition shapes 306. The base width (Wb) 308 may be approximately the same in two or more directions. For example, the base width (Wb) 308 may be the same in two perpendicular directions that extend parallel to the substrate 102. Alternatively, the base width (Wb) 308 may differ along different directions.

FIG. 4 illustrates rounded structures 400 of the template layer 114 in accordance with one embodiment. The shapes of the rounded structures 400 differ from the shapes of the peak structures 200 shown in FIG. 2 and the valley structures 300 shown in FIG. 3, but may be defined by the one or more of the parameters described above in connection with FIGS. 2 and 3. For example, the rounded structures 400 may be defined by a peak height (Hpk) 402, a pitch 404, a transitional shape 406, and a base width (Wb) 408. The rounded structures 400 are formed as protrusions of an upper surface 414 of the template layer 114 that extend upward from a base film 410 of the template layer 114. The rounded structures 400 may have an approximately parabolic or rounded shape. In operation, the rounded structures 400 may vary slightly from the shape of an ideal parabola. While the rounded structures 400 are represented as parabolas in the two dimensional view of FIG. 4, alternatively the rounded structures 400 may have the shape of a three dimensional paraboloid, pyramid, or cone that extends upward away from the substrate 102.

In general, the rounded structures 400 project upward from the base film 410 and away from the substrate 102 to rounded high points 412, or rounded apexes. The peak height (Hpk) 402 represents the average or median distance between the base film 410 and the high points 412. The pitch 404 represents the average or median distance between the same or common points of the rounded structures 400. For example, the pitch 404 may be the distance between the high points 412. The pitch 404 may be approximately the same in two or more directions. For example, the pitch 404 may be the same in two perpendicular directions that extend parallel to the substrate 102. Alternatively, the pitch 404 may differ along different directions. In another example, the pitch 404 may represent the distance between midpoints of the transition shapes 406 that extend between the rounded structures 400. Alternatively, the pitch 404 may represent the average or median distance between other similar points on adjacent rounded structures 400.

The transitional shape 406 is the general shape of the upper surface 414 between the rounded structures 400. As shown in the illustrated embodiment, the transitional shape 406 can take the form of a flat “facet.” Alternatively, the flat facet shape may be a cone or pyramid when viewed in three dimensions. The base width (Wb) 408 represents the average or median distance between the transition shapes 406 on opposite sides of a rounded structure 400. Alternatively, the base width (Wb) 408 may represent the distance between the midpoints of the transition shapes 406.

In accordance with one embodiment, the pitch 204, 302, 402 and/or base width (Wb) 210, 308, 408 of the structures 200, 300, 400 are approximately 400 nanometers to approximately 1500 nanometers. Alternatively, the pitch 204, 302, 402 of the structures 200, 300, 400 may be smaller than approximately 400 nanometers or larger than approximately 1500 nanometers. The average or median peak height (Hpk) 204, 302, 402 of the structures 200, 300, 400 may be approximately 25 to 80% of the pitch 206, 304, 404 for the corresponding structure 200, 300, 400. Alternatively, the average peak height (Hpk) 204, 302, 402 may be a different fraction of the pitch 206, 304, 404. The base width (Wb) 210, 308, 408 may be approximately the same as the pitch 206, 304, 404. In another embodiment, the base width (Wb) 210, 308, 408 may differ from the pitch 206, 304, 404. The base width (Wb) 210, 308, 408 may be approximately the same in two or more directions. For example, the base width (Wb) 210, 308, 408 may be the same in two perpendicular directions that extend parallel to the substrate 102. Alternatively, the base width (Wb) 210, 308, 408 may differ along different directions.

The parameters of the structures 200, 300, 400 in the template layer 114 may vary based on whether the PV cell 100 (shown in FIG. 1) is a dual- or triple junction cell 100 and/or on which of the semiconductor films or layers in the upper and/or lower layer stacks 106, 108 (shown in FIG. 1) is the current-limiting layer. For example, the upper and lower silicon layer stacks 106, 108 may include two or more stacks of N-I-P and/or P-I-N doped amorphous or doped microcrystalline silicon layers. One or more parameters described above may be based on which of the semiconductor layers in the N-I-P and/or P-I-N stacks is the current-limiting layer. For example, one or more of the layers in the N-I-P and/or P-I-N stacks may limit the amount of current that is generated by the PV cell 100 when light strikes the PV cell 100. One or more of the parameters of the structures 200, 300, 400 may be based on which of these layers is the current-limiting layer.

In one embodiment, if the PV cell 100 (shown in FIG. 1) includes a microcrystalline silicon layer in the upper and/or lower silicon layer stack 106, 108 (shown in FIG. 1) and the microcrystalline silicon layer is the current limiting layer of the upper and lower silicon layer stacks 106, 108, the pitch 206, 304, 404 of the structures 200, 300, 400 in the template layer 114 below the microcrystalline silicon layer may be between approximately 500 and 1500 nanometers. The microcrystalline silicon layer has an energy bandgap that corresponds to infrared light having wavelengths between approximately 500 and 1500 nanometers. For example, the structures 200, 300, 400 may reflect an increased amount of infrared light having wavelengths of between 500 and 1500 nanometers if the pitch 206, 404, 504 is approximately matched to the wavelengths. The transitional shape 208, 306, 406 of the structures 200, 300, 400 may be a flat facet and the base width (Wb) 210, 308, 408 may be 60% to 100% of the pitch 206, 304, 404. The peak height (Hpk) 204, 302, 402 may be between 25% to 75% of the pitch 206, 304, 404. For example, a ratio of the peak height (Hpk) 204, 302, 402 to the pitch 206, 304, 404 may provide scattering angles in the structures 200, 300, 400 that reflect more light back into the upper and/or lower silicon layer stacks 106, 108 relative to other ratios.

In another example, if the PV cell 100 (shown in FIG. 1) includes one layer stack 106 or 108 being amorphous silicon layers and the other layer stack 106 or 108 being microcrystalline semiconductor layers, the range of pitches 206, 304, 404 for the template layer 114 may vary based on which of the upper and lower layer stacks 106, 108 is the current limiting stack. If the upper silicon layer stack 106 includes a microcrystalline N-I-P or P-I-N doped semiconductor layer stack, the lower silicon layer stack 108 includes an amorphous N-I-P or P-I-N doped semiconductor layer stack, and the upper silicon layer stack 106 is the current limiting layer, then the pitch 206, 304, 504 may be between approximately 500 and 1500 nanometers. In contrast, if the lower silicon layer stack 108 is the current limiting layer, then the pitch 206, 304, 404 may be between approximately 350 and 1000 nanometers.

Returning to the discussion of the cell 100 shown in FIG. 1, the template layer 114 may be formed in accordance with one or more of the embodiments described in the '880 Application. For example, the template layer 114 may be formed by depositing an amorphous silicon layer onto the substrate 102 followed by texturing the amorphous silicon using reactive ion etching through silicon dioxide spheres placed on the upper surface of the amorphous silicon. Alternatively, the template layer 114 may be formed by sputtering an aluminum and tantalum bilayer on the substrate 102 and then anodizing the template layer 114. In another embodiment, the template layer may be formed by depositing a film of textured fluorine-doped tin oxide (SnO₂:F) using atmospheric chemical vapor deposition. One or more of these films of the template layer 114 may be obtained from a vendor such as Asahi Glass Company or Pilkington Glass. In an alternative embodiment, the template layer 114 may be formed by applying an electrostatic charge to the substrate 102 and then placing the charged substrate 102 in an environment having oppositely charged particles. Electrostatic forces attract the charged particles to the substrate 102 to form the template layer 114. The particles are subsequently permanently attached to the substrate 102 by depositing an adhesive “glue” layer (not shown) onto the particles in a subsequent deposition step or by annealing the particles and substrate 102. Examples of particle materials include faceted ceramics and diamond like material particles such as silicon carbide, alumina, aluminum nitride, diamond, and CVD diamond.

The lower electrode layer 112 is deposited above the template layer 114. The lower electrode layer 112 is comprised of a conductive reflector layer 116 and a conductive buffer layer 118. The reflector layer 116 is deposited above the template layer 114. For example, the reflector layer 116 may be directly deposited onto the template layer 114. The reflector layer 116 has a textured upper surface 120 that is dictated by the template layer 114. For example, the reflector layer 116 may be deposited onto the template layer 114 such that the reflector layer 116 includes structures (not shown) that are similar in size and/or shape to the structures 200, 300, 400 (shown in FIGS. 2 through 4) of the template layer 114.

The reflector layer 116 may include, or be formed from, a reflective conductive material, such as silver and/or titanium. Alternatively, the reflector layer 116 may include, or be formed from, aluminum or an alloy that includes silver or aluminum. The reflector layer 116 is approximately 100 to 300 nanometers in thickness and may be deposited by sputtering the material(s) of the reflector layer 116 onto the template layer 114.

The reflector layer 116 provides a conductive layer and a reflective surface for reflecting light upward into the upper and lower active silicon layer stacks 106, 108. For example, a portion of the light that is incident on the cover layer 104 and that passes through the upper and lower active silicon layer stacks 106, 108 may not be absorbed by the upper and lower layer stacks 106, 108. This portion of the light may reflect off of the reflector layer 116 back into the upper and lower layer stacks 106, 108 such that the reflected light may be absorbed by the upper and/or lower layer stacks 106, 108. The textured upper surface 120 of the reflector layer 116 increases the amount of light that is absorbed, or “trapped” via partial or full scattering of the light into the upper and lower active silicon layer stacks 106, 108. The peak height (Hpk) 204, 302, 402, pitch 206, 304, 404, transitional shape 208, 306, 406, and/or base width (Wb) 210, 308, 408 (shown in FIGS. 2 through 4)) may be varied to increase the amount of light that is trapped in the upper and lower layer stacks 106, 108 for a desired or predetermined range of wavelengths of incident light.

The buffer layer 118 is deposited above the reflector layer 116 and may be directly deposited onto the reflector layer 116. The buffer layer 118 provides an electric contact to the lower active silicon layer stack 108. For example, the buffer layer 118 may include, or be formed from, a transparent conductive oxide (TCO) material that is electrically coupled with the lower active silicon layer stack 108. In one embodiment, the buffer layer 118 includes aluminum doped zinc oxide, zinc oxide and/or indium tin oxide. In one embodiment, the buffer layer 118 includes SnO₂:F. The buffer layer 118 may be deposited in a thickness of approximately 50 to 500 nanometers, although a different thickness may be used.

In one embodiment, the buffer layer 118 provides a chemical buffer between the reflector layer 116 and the lower active silicon layer stack 108. For example, the buffer layer 118 may prevent chemical attack on the lower active silicon layer stack 108 by the reflector layer 116 during processing and manufacture of the cell 100. The buffer layer 118 impedes or prevents contamination of the silicon in the lower layer stack 108 and may reduce plasmon absorption losses in the lower layer stack 108.

The buffer layer 118 may provide an optical buffer between the reflector layer 116 and the lower active silicon layer stack 108. For example, the buffer layer 118 may be a light transmissive layer that is deposited in a thickness that is based on a predetermined range of wavelengths that is reflected off of the reflector layer 116. The thickness of the buffer layer 118 may permit certain wavelengths of light to pass through the buffer layer 118, reflect off of the reflector layer 116, pass back through the buffer layer 118 and into the lower layer stack 108. By way of example only, the buffer layer 118 may be deposited at a thickness of approximately 75 to 80 nanometers.

The lower active silicon layer stack 108 is deposited above, or directly onto, the buffer layer 118. In one embodiment, the lower layer stack 108 is deposited at a thickness of approximately 1 to 3 micrometers, although the lower layer stack 108 may be deposited at a different thickness. The lower layer stack 108 includes three sublayers 122, 124, 126 of silicon. In one embodiment, the sublayers 122, 124, 126 are n-doped, intrinsic and p-doped microcrystalline silicon films, respectively, that are deposited using plasma enhanced chemical vapor deposition (PECVD) at relatively low deposition temperatures. For example, the sublayers 122, 124, 126 may be deposited at a temperature in the range of approximately 160 to 250 degrees Celsius. The deposition of the sublayers 122, 124, 126 at relatively lower deposition temperatures may reduce interdiffusion of dopants from one sublayer 122, 124, 126 into another sublayer 122, 124, 126. In addition, use of lower deposition temperatures in a given sublayer 122, 124, 126 may help prevent hydrogen evolution from the underlying sublayers 122, 124, 126 in the upper and lower layer stacks 106, 108, respectively.

Alternatively, the lower layer stack 108 may be deposited at relatively high deposition temperatures. For example, the lower layer stack 108 may be deposited at a temperature in the range of approximately 250 to 350 degrees Celsius. As the deposition temperature increases, the average grain size of crystalline structure in the lower layer stack 108 may increase and may lead to an increase in the absorption of infrared light in the lower layer stack 108. Therefore, the lower layer stack 108 may be deposited at the higher temperatures in order to increase the average grain size of the silicon crystals in the lower layer stack 108. In addition, depositing the lower layer stack 108 at higher temperatures may make the lower layer stack 108 more thermally stable during the subsequent deposition of the upper layer stack 106. As described below, the top sublayer 126 of the lower layer stack 108 may be a p-doped silicon film. In such an embodiment, the bottom and middle sublayers 122, 124 of the lower layer stack 108 may be deposited at the relatively high deposition temperatures within the range of approximately 250 to 350 degrees Celsius while the top sublayer 126 is deposited at a relatively lower temperature within the range of approximately 150 to 250 degrees Celsius. Alternatively, the top sublayer 126 may be deposited at a temperature of at least 160 degrees Celsius. The p-doped sublayer 126 is deposited at the lower temperature to reduce the amount of interdiffusion between the p-doped top sublayer 126 and the intrinsic middle sublayer 124. Alternatively, the p-doped sublayer 126 is deposited at a higher deposition temperature, such as approximately 250 to 350 degrees Celsius, for example.

The sublayers 122, 124, 126 may have an average grain size of at least approximately 10 nanometers. In another embodiment, the average grain size in the sublayers 122, 124, 126 is at least approximately 20 nanometers. Alternatively, the average grain size of the sublayers 122, 124, 126 is at least approximately 50 nanometers. In another embodiment, the average grain size is at least approximately 100 nanometers. Optionally, the average grain size may be at least approximately 1 micrometer. The average grain size in the sublayers 122, 124, 126 may be determined by a variety of methods. For example, the average grain size can be measured using Transmission Electron Microscopy (“TEM”). In such an example, a thin sample of the sublayers 122, 124, 126 is obtained. For example, a sample of one or more of the sublayers 122, 124, 126 having a thickness of approximately 1 micrometer or less is obtained. A beam of electrons is transmitted through the sample. The beam of electrons may be rastered across all or a portion of the sample. As the electrons pass through the sample, the electrons interact with the crystalline structure of the sample. The path of transmission of the electrons may be altered by the sample. The electrons are collected after the electrons pass through the sample and an image is generated based on the collected electrons. The image provides a two-dimensional representation of the sample. The crystalline grains in the sample may appear different from the amorphous portions of the sample. Based on this image, the size of crystalline grains in the sample may be measured. For example, the surface area of several crystalline grains appearing in the image can be measured and averaged. This average is the average crystalline grain size in the sample in the location where the sample was obtained. For example, the average may be the average crystalline grain size in the sublayers 122, 124, 126 from which the sample was obtained.

The bottom sublayer 122 may be a microcrystalline layer of n-doped silicon. In one embodiment, the bottom sublayer 122 is deposited in a PECVD chamber with an operating frequency of approximately 13.56 MHz using a source gas combination of hydrogen (H), silane (SiH₄) and phosphine, or phosphorus trihydride (PH₃) at a vacuum pressure of approximately 2 to 3 ton and at an energy of approximately 500 to 1000 Watts. The ratio of source gases used to deposit the bottom sublayer 122 may be approximately 200 to 300 parts hydrogen gas to approximately 1 part silane to approximately 0.01 part phosphine.

The middle sublayer 124 may be a microcrystalline layer of intrinsic silicon. For example, the middle sublayer 124 may include silicon that is not doped or that has a dopant concentration that less than 10¹⁸/cm³. In one embodiment, the middle sublayer 124 is deposited in a PECVD chamber with an operating frequency of approximately 13.56 MHz using a source gas combination of hydrogen (H) and silane (SiH₄) at a vacuum pressure of approximately 9 to 10 ton and at an energy of approximately 2 to 4 kilowatts. The ratio of source gases used to deposit the middle sublayer 124 may be approximately 50 to 65 parts hydrogen gas to approximately 1 part silane.

The top sublayer 126 may be a microcrystalline layer of p-doped silicon. Alternatively, the top sublayer 126 may be a protocrystalline layer of p-doped silicon. In one embodiment, the top sublayer 126 is deposited in a PECVD chamber with an operating frequency of approximately 13.56 MHz using a source gas combination of hydrogen (H), silane (SiH₄) and trimethyl boron (B(CH₃)₃, or TMB) at a vacuum pressure of approximately 2 to 3 ton and at an energy of approximately 500 to 1000 Watts. The ratio of source gases used to deposit the top sublayer 126 may be approximately 200 to 300 parts hydrogen gas to approximately 1 part silane to approximately 0.01 part phosphine. TMB may be used to dope the silicon in the top sublayer 126 with boron. Using TMB to dope the silicon in the top sublayer 126 may provide better thermal stability than using a different type of dopant, such as boron trifluoride (BF₃) or diborane (B₂H₆). For example, the use of TMB to dope silicon may result in less boron diffusing from the top sublayer 126 into adjacent layers, such as the middle sublayer 124, during the deposition of subsequent layers when compared to using trifluoride or diborane. By way of example only, using TMB to dope the top sublayer 126 may result in less boron diffusing into the middle sublayer 124 than when trifluoride or diborane is used to dope the top sublayer 126 during deposition of the upper layer stack 106.

The three sublayers 122, 124, 126 form an N-I-P junction or N-I-P stack of active silicon layers. As the lower layer stack 108, the three sublayers 122, 124, 126 have an energy band gap of approximately 1.1 eV. Alternatively, the lower layer stack 108 may have a different energy band gap. The lower layer stack 108 has a different energy band gap than the upper layer stack 106, as described below. The different energy band gaps of the upper and lower layer stacks 106, 108 permit the upper and lower layer stacks 106, 108 to absorb different wavelengths of incident light.

In one embodiment, an intermediate reflector layer 128 is deposited between the upper and lower layer stacks 106, 108. For example, the intermediate reflector layer 128 may be deposited directly on the lower layer stack 108. Alternatively, the intermediate reflector layer 128 is not included in the cell 100 and the upper layer stack 106 is deposited onto the lower layer stack 108. The intermediate reflector layer 128 partially reflects light into the upper layer stack 106 and permits some of the light to pass through the intermediate reflector layer 128 and into the lower layer stack 108. For example, the intermediate reflector layer 128 may reflect a subset of the spectrum of wavelengths of light that is incident on the cell 100 back up and into the upper layer stack 106.

The intermediate reflector layer 128 includes, or is formed from, a partially reflective material. For example, the intermediate reflector layer 128 may be formed from titanium dioxide (TiO₂), zinc oxide (ZnO), aluminum doped zinc oxide (AZO), indium tin oxide (ITO), doped silicon oxide or doped silicon nitride. In one embodiment, the intermediate reflector layer 128 is approximately 10 to 200 nanometers in thickness, although a different thickness may be used.

The upper active silicon layer stack 106 is deposited above the lower active silicon layer stack 108. For example, the upper layer stack 106 may be directly deposited onto the intermediate reflector layer 128 or onto the lower layer stack 108. In one embodiment, the upper layer stack 106 is deposited at a thickness of approximately 200 to 400 nanometers, although the upper layer stack 106 may be deposited at a different thickness. The upper layer stack 106 includes three sublayers 130, 132, 134 of silicon.

In one embodiment, the sublayers 130, 132, 134 are n-doped, intrinsic, and p-doped amorphous silicon (a-Si:H) films, respectively, that are deposited using plasma enhanced chemical vapor deposition (PECVD) at relatively low deposition temperatures. For example, the sublayers 130, 132, 134 may be deposited at a temperature of approximately 185 to 250 degrees Celsius. In another example, the sublayers 130, 132, 134 may be deposited at temperatures between 185 and 225 degrees Celsius. Alternatively, the p-doped sublayer 134 is deposited at a temperature that is lower than the temperatures at which the n-doped and intrinsic sublayers 130, 132 are deposited. For example, the p-doped sublayer 134 may be deposited at a temperature of approximately 120 to 200 degrees Celsius while the intrinsic and/or n-doped sublayers 132, 130 are deposited at temperatures of at least 200 degrees Celsius. By way of example only, the intrinsic and/or n-doped sublayers 132, 130 may be deposited at a temperature of approximately 250 to 350 degrees Celsius.

The deposition of one or more of the sublayers 130, 132, 134 at relatively lower deposition temperatures may reduce interdiffusion of dopants between sublayers 122, 124, 126 in the lower layer stack 108 and/or between sublayers 130, 132, 134 in the upper layer stack 106. The diffusion of dopants in and between the sublayers 122, 124, 126 and in and between the sublayers 130, 132, 134 may be based on the temperature at which the sublayers 122, 124, 126 and 130, 132, 134 are heated. For example, the interdiffusion of dopants between the sublayers 122, 124, 126, 130, 132, 134 can increase with exposure to increasing temperatures. Using lower deposition temperatures may reduce the amount of dopant diffusion in the sublayers 122, 124, 126 and/or in the sublayers 130, 132, 134. Use of lower deposition temperatures in a given sublayer 122, 124, 126, 130, 132, 134 may reduce hydrogen evolution from the underlying sublayers 122, 124, 126, 130, 132, 134 in the upper and lower layer stacks 106, 108, respectively.

The deposition of the sublayers 130, 132, 134 at relatively lower deposition temperatures may increase the energy band gap of the upper layer stack 106 relative to amorphous silicon layers that are deposited at higher deposition temperatures. For example, depositing the sublayers 130, 132, 134 as amorphous silicon layers at temperatures between approximately 185 to 250 degrees Celsius may cause the band gap of the upper layer stack 106 to be approximately 1.85 to 1.95 eV. Increasing the band gap of the upper layer stack 106 may cause the sublayers 130, 132, 134 to absorb a smaller subset of the spectrum of wavelengths in the incident light, but may increase the electric potential difference generated in the cell 100.

Alternatively, the upper layer stack 106 may be deposited at relatively high deposition temperatures. For example, the upper layer stack 106 may be deposited at a temperature in the range of approximately 250 to 350 degrees Celsius. As the deposition temperature of amorphous silicon increases, the energy band gap of the silicon decreases. For example, depositing the sublayers 130, 132, 134 as amorphous silicon layers with relatively little to no germanium in the layers at temperatures between approximately 250 and 350 degrees Celsius may cause the band gap of the upper layer stack 106 to be at least 1.65 eV. In one embodiment, the band gap of the upper layer stack 106 formed from amorphous silicon with a germanium content in the silicon being 0.01% or less is 1.65 to 1.80 eV. The germanium content may represent the fraction or percentage of germanium in the upper layer stack 106 relative to other materials, such as silicon, in the upper layer stack 106. Decreasing the band gap of the upper layer stack 106 may cause the sublayers 130, 132, 134 to absorb a larger subset of the spectrum of wavelengths in the incident light and may result in a greater electric current to be generated by a plurality of cells 100 electrically interconnected in a series.

Deposition of the upper layer stack 106 at relatively high deposition temperatures may be verified by measuring the hydrogen content of the upper layer stack 106. In one embodiment, the final hydrogen content of the upper layer stack 106 is less than approximately 8 atomic percent if the upper layer stack 106 was deposited at temperatures above approximately 250 degrees Celsius. The final hydrogen content in the upper layer stack 106 may be measured using Secondary Ion Mass Spectrometer (SIMS). A sample of the upper layer stack 106 is placed into the SIMS. The sample is then sputtered with an ion beam. The ion beam causes secondary ions to be ejected from the sample. The secondary ions are collected and analyzed using a mass spectrometer. The mass spectrometer then determines the molecular composition of the sample. The mass spectrometer can determine the atomic percentage of hydrogen in the sample.

Alternatively, the final hydrogen concentration in upper layer stack 106 may be measured using Fourier Transform Infrared spectroscopy (“FTIR”). In FTIR, a beam of infrared light is then sent through a sample of the upper layer stack 106. Different molecular structures and species in the sample may absorb the infrared light differently. Based on the relative concentrations of the different molecular species in the sample, a spectrum of the molecular species in the sample is obtained. The atomic percentage of hydrogen in the sample can be determined from this spectrum. Alternatively, several spectra are obtained and the atomic percentage of hydrogen in the sample is determined from the group of spectra.

As described below, the top sublayer 134 may be a p-doped silicon film. In such an embodiment, the bottom and middle sublayers 130, 132 may be deposited at the relatively high deposition temperatures within the range of approximately 250 to 350 degrees Celsius while the top sublayer 134 is deposited at a relatively lower temperature within the range of approximately 150 to 200 degrees Celsius. The p-doped top sublayer 134 is deposited at the lower temperature to reduce the amount of interdiffusion between the p-doped top sublayer 134 and the intrinsic middle sublayer 132. Depositing the p-doped top sublayer 134 at a lower temperature may increase the band gap of the sublayer 134 and/or makes the sublayer 134 more transmissive of visible light.

The bottom sublayer 130 may be an amorphous layer of n-doped silicon. In one embodiment, the bottom sublayer 130 is deposited in a PECVD chamber with an operating frequency of approximately 13.56 MHz using a source gas combination of hydrogen (H₂), silane (SiH₄) and phosphine, or phosphorus trihydride (PH₃) at a vacuum pressure of approximately 2 to 3 ton and at an energy of approximately 500 to 1000 Watts. The ratio of source gases used to deposit the bottom sublayer 130 may be approximately 200 to 300 parts hydrogen gas to approximately 1 part silane to approximately 0.01 part phosphine.

The middle sublayer 132 may be an amorphous layer of intrinsic silicon. Alternatively, the middle sublayer 132 may be a polymorphous layer of intrinsic silicon. In one embodiment, the middle sublayer 132 is deposited in a PECVD chamber with an operating frequency of approximately 13.56 MHz using a source gas combination of hydrogen (H) and silane (SiH₄) at a vacuum pressure of approximately 1 to 3 ton and at an energy of approximately 200 to 400 Watts. The ratio of source gases used to deposit the middle sublayer 132 may be approximately 4 to 12 parts hydrogen gas to approximately 1 part silane.

In one embodiment, the top sublayer 134 may be a protocrystalline layer of p-doped silicon. Alternatively, the top sublayer 134 is an amorphous layer of p-doped silicon. In one embodiment, the top sublayer 134 is deposited in a PECVD chamber with an operating frequency of approximately 13.56 MHz using a source gas combination of hydrogen (H), silane (SiH₄), and boron trifluoride (BF₃), TMB, or diborane (B₂H₆) at a vacuum pressure of approximately 2 to 3 ton and at an energy of approximately 500 to 1000 Watts. The ratio of source gases used to deposit the top sublayer 126 may be approximately 200 to 300 parts hydrogen gas to approximately 1 part silane to approximately 0.01 part dopant gas.

The three sublayers 130, 132, 134 form an NIP junction of active silicon layers. The three sublayers 130, 132, 134 have an energy band gap that differs from the energy band gap of the lower layer stack 108. For example, the energy band gap of the upper layer stack 106 may be at least about 50% greater than the lower layer stack 108. In another example, the upper layer stack 106 may have an energy band gap that is at least about 60% greater than the energy band gap of the lower layer stack 108. Alternatively, the energy band gap of the upper layer stack 106 may be at least about 40% greater than the energy band gap of the lower layer stack 108. The different energy band gaps of the upper and lower layer stacks 106, 108 permit the upper and lower layer stacks 106, 108 to absorb different wavelengths of incident light and may increase the efficiency of the cell 100 in converting incident light into electric potential and/or current.

The energy band gaps of the upper and lower layer stack 106, 108 may be measured using ellipsometry. Alternatively, an external quantum efficiency (EQE) measurement may be used to obtain the energy band gaps of the upper and lower layer stacks 106, 108. The EQE measurement is obtained by varying wavelengths of light that are incident upon a semiconductor layer or layer stack and measuring the efficiency of the layer or layer stack in converting incident photons into electrons that reach the external circuit. Based on the efficiencies of the upper and lower layer stacks 106, 108 in converting incident light into electrons at different wavelengths, the energy band gaps of the upper and lower layer stacks 106, 108 may be derived. For example, each of the upper and lower layer stacks 106, 108 may be more efficient in converting incident light having an energy that is greater than the band gap of the upper or lower layer stack 106, 108 than in converting light of a different energy.

The upper electrode layer 110 is deposited above the upper layer stack 106. For example, the upper electrode layer 110 may be directly deposited onto the upper layer stack 106. The upper electrode layer 110 includes, or is formed from, a conductive and light transmissive material. For example, the upper electrode layer 110 may be formed from a transparent conductive oxide. Examples of such materials include zinc oxide (ZnO), tin oxide (SnO₂), fluorine doped tin oxide (SnO₂:F), tin-doped indium oxide (ITO), titanium dioxide (TiO₂), and/or aluminum-doped zinc oxide (Al:ZnO). The upper electrode layer 110 can be deposited in a variety of thicknesses. In some embodiments, the upper electrode layer 110 is approximately 50 nanometers to 2 micrometers thick.

In one embodiment, the upper electrode layer 110 is formed from a 60 to 90 nanometer thick layer of ITO or Al:ZnO. The upper electrode layer 110 may function as both a conductive material and a light transmissive material with a thickness that creates an anti-reflection (AR) effect in the upper electrode layer 110 of the cell 100. For example, the upper electrode layer 110 may permit a relatively large percentage of one or more wavelengths of incident light to propagate through the upper electrode layer 110 while reflecting a relatively small percentage of the wavelength(s) of light to be reflected by the upper electrode layer 110 and away from the active layers of the cell 100. By way of example only, the upper electrode layer 110 may reflect approximately 5% or less of one or more wavelengths of incident light. In another example, the upper electrode layer 110 may reflect approximately 3% or less of the light. In another embodiment, the upper electrode layer 110 may reflect approximately 2% or less of the light. In yet another example, the upper electrode layer 110 may reflect approximately 0.5% or less of the light.

The thickness of the upper electrode layer 110 may be adjusted to increase the amount of incident light that propagates through the upper electrode layer 110 and down into the upper and lower layer stacks 106, 108. Although the sheet resistance of relatively thin upper electrode layers 110 may be relatively high, such as approximately 20 to 50 ohms per square, the relatively high sheet resistance of the upper electrode layer 110 may be compensated for by decreasing a width of the upper electrode layers 110, as described below.

An adhesive layer 136 is deposited above the upper electrode layer 110. For example, the adhesive layer 136 may be deposited directly on the upper electrode layer 110. Alternatively, the adhesive layer 136 is not included in the cell 100. The adhesive layer 136 secures the cover layer 104 to the upper electrode layer 110. The adhesive layer 136 may prevent moisture ingress into the cell 100. The adhesive layer 136 may include a material such as a polyvinyl butyral (“PVB”), surlyn, or ethylene-vinyl acetate (“EVA”) copolymer, for example.

The cover layer 104 is placed above the adhesive layer 136. Alternatively, the cover layer 104 is placed on the upper electrode layer 110. The cover layer 104 includes or is formed from a light transmissive material. In one embodiment, the cover layer 104 is a sheet of tempered glass. The use of tempered glass in the cover layer 104 may help to protect the cell 100 from physical damage. For example, a tempered glass cover layer 104 may help protect the cell 100 from hailstones and other environmental damage. In another embodiment, the cover layer 104 is a sheet of soda-lime glass, low-iron tempered glass, or low-iron annealed glass. The use of a highly transparent, low-iron glass cover layer 104 can improve the transmission of light to the silicon layer stacks 106 and 108. Optionally, an AR coating (not shown) may be provided on the top of the cover layer 104.

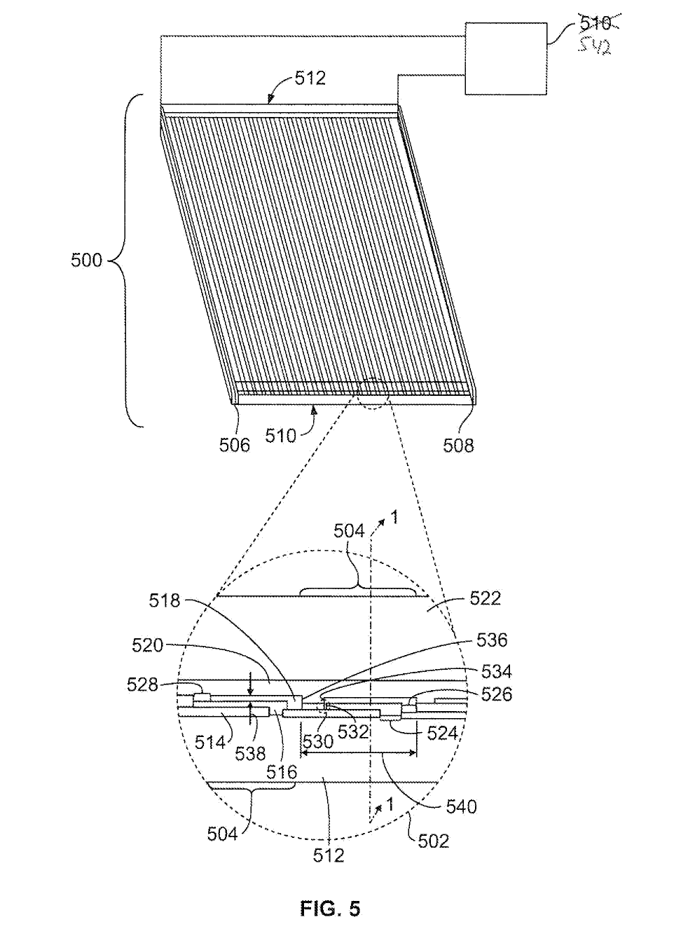

FIG. 5 is a schematic diagram of a photovoltaic device 500 and a magnified view 502 of the device 500 according to one embodiment. The device 500 includes a plurality of photovoltaic cells 504 electrically coupled in series with one another. The cells 504 may be similar to the cells 100 (shown in FIG. 1). For example, each of the cells 504 may have a tandem arrangement of upper and lower layer stacks 106, 108 that each absorb a different subset of the spectrum of wavelengths of light. The schematic illustration of FIG. 1 may be a cross-sectional view along line 1-1 in FIG. 5. The device 500 may include many cells 504 electrically coupled with one another in series. By way of example only, the device 500 may have twenty-five, fifty, or one hundred or more cells 504 connected with one another in a series. Each of the outermost cells 504 also may be electrically connected with one of a plurality of leads 506, 508. The leads 506, 508 extend between opposite ends 510, 512 of the device 500. The leads 506, 508 are connected with an external electrical load 542. The electric current generated by the device 500 is applied to the external load 542.

As described above, each of the cells 504 includes several layers. For example, each cell 504 includes a substrate 512 that is similar to the substrate 102 (shown in FIG. 1), a lower electrode layer 514 that is similar to the lower electrode layer 112 (shown in FIG. 1), a tandem silicon layer stack 516, an upper electrode layer 518 that is similar to the upper electrode layer 110 (shown in FIG. 1), an adhesive layer 520 that is similar to the adhesive layer 136 (shown in FIG. 1) and a cover layer 522 that is similar to the cover layer 104 (shown in FIG. 1). The tandem silicon layer stack 516 includes upper and lower stacks of active silicon layers that each absorb or trap a different subset of the spectrum of wavelengths of light that is incident on the device 500. For example, the tandem layer stack 516 may include the an upper layer stack that is similar to the upper active silicon layer stack 106 (shown in FIG. 1) and a lower layer stack that is similar to the lower active silicon layer stack 108 (shown in FIG. 1). The upper and lower layer stacks in the tandem layer stack 516 may be separated from one another by an intermediate reflector layer that is similar to the intermediate reflector layer 128 (shown in FIG. 1).

The upper electrode layer 518 of one cell 504 is electrically coupled with the lower electrode layer 514 in a neighboring, or adjacent, cell 100. As described above, the collection of the electrons and holes at the upper and lower electrode layers 518, 514 generates a voltage difference in each of the cells 504. The voltage difference in the cells 504 may be additive across multiple cells 504 in the device 500. The electrons and holes flow through the upper and lower electrode layers 518, 514 in one cell 504 to the opposite electrode layer 518, 514 in a neighboring cell 504. For example, if the electrons in a first cell 504 flow to the lower electrode layer 514 in a when light strikes the tandem layer stack 516, then the electrons flow through the lower electrode layer 514 of the first cell 504 to the upper electrode layer 518 in a second cell 504 that is adjacent to the first cell 504. Similarly, if the holes flow to the upper electrode layer 518 in the first cell 504, then the holes flow from the upper electrode layer 518 in the first cell 504 to the lower electrode layer 514 in the second cell 504. Electric current and voltage is generated by the flow of electrons and holes through the upper and lower electrode layers 518, 514. The current is applied to the external load 542.

The device 500 may be a monolithically integrated solar module similar to one or more of the embodiments described in co-pending U.S. Nonprovisional patent application Ser. No. 12/569,510, filed Sep. 29, 2009, and entitled “Monolithically-Integrated Solar Module” (“'510 Application”). The entire disclosure of the '510 Application is incorporated by reference herein. For example, in order to create the shapes of the lower and upper electrode layers 514, 518 and the tandem layer stack 516 in the device 500, the device 500 may be fabricated as a monolithically integrated module as described in the '510 Application. In one embodiment, portions of the lower electrode layer 514 are removed to create lower separation gaps 524. The portions of the lower electrode layer 514 may be removed using a patterning technique on the lower electrode layer 514. For example, a laser light that scribes the lower separation gaps 524 in the lower electrode layer 514 may be used to create the lower separation gaps 524. After removing portions of the lower electrode layer 514 to create the lower separation gaps 524, the remaining portions of the lower electrode layer 514 are arranged as linear strips extending in directions transverse to the plane of the magnified view 502.

The tandem layer stack 516 is deposited on the lower electrode layer 514 such that the tandem layer stack 516 fills in the volumes in the lower separation gaps 524. The tandem layer stack 516 is then exposed to a focused beam of energy, such as a laser beam, to remove portions of the tandem layer stack 516 and provide inter-layer gaps 526 in the tandem layer stack 516. The inter-layer gaps 526 separate the tandem layer stacks 516 of adjacent cells 504. After removing portions of the tandem layer stacks 516 to create the inter-layer gaps 526, the remaining portions of the tandem layer stacks 516 are arranged as linear strips extending in directions transverse to the plane of the magnified view 502.

The upper electrode layer 518 is deposited on the tandem layer stack 516 and on the lower electrode layer 514 in the inter-layer gaps 526. In one embodiment, the conversion efficiency of the device 500 may be increased by depositing a relatively thin upper electrode layer 518 with a thickness that is adjusted or tuned to provide an anti-reflection effect. For example, a thickness 538 of the upper electrode layer 518 may be adjusted to increase the amount of visible light that is transmitted through the upper electrode layer 518 and into the tandem layer stack 516. The amount of visible light that is transmitted through the upper electrode layer 518 may vary based on the wavelength of the incident light and the thickness of the upper electrode layer 518. One thickness of the upper electrode layer 518 may permit more light of one wavelength to propagate through the upper electrode layer 518 than light of other wavelengths. By way of example only, the upper electrode layer 518 may be deposited at a thickness of approximately 60 to 90 nanometers.

In terms of increasing the total power generated by the PV device 500, the increased power output arising from the anti-reflection effect provided by a thin upper electrode layer 518 may be sufficient to overcome at least some, if not all, of energy losses that may occur in the upper electrode layer 518. For example, some I²R losses of the photocurrent that is generated by the cell 504 may occur in the relatively thin upper electrode layer 518 due to the resistance of the upper electrode layer 518. But, an increased amount of photocurrent may be generated due to the thickness of the upper electrode layer 518 being based on a wavelength of the incident light to increase the amount of incident light that passes through the upper electrode layer 518. The increased amount of photocurrent may result from an increased amount of light passing through the upper electrode layer 518. The increased photocurrent may overcome or at least partially compensate for the I²R power loss associated with the relatively high sheet resistance of a thin upper electrode layer 518.

By way of example only, in a cell 504 having one amorphous silicon junction layer stack and one microcrystalline silicon junction stacked in series in the tandem layer stack 516, an output voltage in the range of approximately 1.25 to 1.5 volts and an electric current density in the range of approximately 10 to 15 milliamps per square centimeter may be achieved. I²R losses in a thin upper electrode layer 518 of the cell 504 may be sufficiently small that a width 540 of the cell 504 may be increased even if the upper electrode layer 518 has a relatively high sheet resistance. For example, the width 540 of the cell 504 may be increased to as large as approximately 0.4 to 1 centimeter even if the sheet resistance of the upper electrode layer 518 is at least 10 ohms per square, such as a sheet resistance of at least approximately 15 to 30 ohms/square. Because the width 540 of the cell 504 can be controlled in the device 500, the I²R power loss in the upper electrode layer 518 may be reduced without the use or addition of a conducting grid on top of a thin upper electrode layer 518.

Portions of the upper electrode layer 518 are removed to create upper separation gaps 528. The upper separation gaps 528 electrically separate portions of the upper electrode layer 518 that are in adjacent cells 504. The upper separation gaps 528 may be created by exposing the upper electrode layer 518 to a focused beam of energy, such as a laser light. The focused beam of energy may locally increase the crystallinity of the tandem layer stack 516 proximate to the upper separation gaps 528. For example, a crystalline fraction of the tandem layer stack 516 in a vertical portion 530 that extends between the upper electrode layer 518 and the lower electrode layer 514 may be increased by exposure to the focused beam of energy. Additionally, the focused beam of energy may cause diffusion of dopants within the tandem layer stack 516. The vertical portion 530 of the tandem layer stack 516 is disposed between the upper and lower electrode layers 518, 514 and below a left edge 534 of the upper electrode layer 518. As shown in FIG. 5, each of the gaps 528 in the upper electrode layer 518 are bounded by the left edge 534 and an opposing right edge 536 of the upper electrode layers 518 in adjacent cells 504.

The crystalline fraction of the tandem layer stack 516 and the vertical portion 530 may be determined by a variety of methods. For example, Raman spectroscopy can be used to obtain a comparison of the relative volume of noncrystalline material to crystalline material in the tandem layer stack 516 and the vertical portion 530. One or more of the tandem layer stack 516 and the vertical portion 530 sought to be examined can be exposed to monochromatic light from a laser, for example. Based on the chemical content and crystal structure of the tandem layer stack 516 and the vertical portion 530, the monochromatic light may be scattered. As the light is scattered, the frequency (and wavelength) of the light changes. For example, the frequency of the scattered light can shift. The frequency of the scattered light is measured and analyzed. Based on the intensity and/or shift in the frequency of the scattered light, the relative volumes of amorphous and crystalline material of the tandem layer stack 516 and the vertical portion 530 being examined can be determined. Based on these relative volumes, the crystalline fraction in the tandem layer stack 516 and the vertical portion 530 being examined may be measured. If several samples of the tandem layer stack 516 and the vertical portion 530 are examined, the crystalline fraction may be an average of the several measured crystalline fractions.

In another example, one or more TEM images can be obtained of the tandem layer stack 516 and the vertical portion 530 to determine the crystalline fraction of the tandem layer stack 516 and the vertical portion 530. One or more slices of the tandem layer stack 516 and the vertical portion 530 being examined are obtained. The percentage of surface area in each TEM image that represents crystalline material is measured for each TEM image. The percentages of crystalline material in the TEM images can then be averaged to determine the crystalline fraction in the tandem layer stack 516 and the vertical portion 530 being examined.

In one embodiment, the increased crystallinity and/or the diffusion of the vertical portion 530 relative to a remainder of the tandem layer stack 516 forms a built-in bypass diode 532 that vertically extends through the thickness of the tandem layer stack 516 in the view shown in FIG. 5. For example, the crystalline fraction and/or interdiffusion of the tandem stack 516 in the vertical portion 530 may be greater than the crystalline fraction and/or interdiffusion in a remainder of the tandem stack 516. Through control of the energy and pulse duration of the focused beam of energy, the built-in bypass diode 532 can be formed through individual ones of the individual cells 504 without creating an electrical short in the individual cells 504. The built-in bypass diode 532 provides an electrical bypass through a cell 504 in the device 500.

Without the built-in bypass diodes 532, a cell 504 that is shaded or no longer exposed to light while the other cells 504 continue to be exposed to light may become reverse biased by the electric potential generated by the exposed cells 504. For example, the electric potential generated by the light-exposed cells 504 may be built up across the shaded cell 504 at the upper and lower electrode layers 518, 514 of the shaded cell 504. As a result, the shaded cell 504 may increase in temperature and, if the shaded cell 504 significantly increases in temperature, the shaded cell 504 may become permanently damaged and/or incinerate. In addition, a shaded cell 504 that does not have a built-in bypass diode 532 may prevent electric potential or current from being generated by the entire device 500.

With the built-in bypass diodes 532, the electric potential generated by the exposed cells 504 may bypass the shaded cell 504 through the bypass diodes 532 formed at the edges of the upper separation gaps 528 of the shaded cell 504. The increased crystallinity of the portion 530 of the tandem layer stack 516 and/or interdiffusion between the upper electrode layer 518 and the portion 530 in the tandem layer stack 516 provides a path for electric current to pass through when the shaded cell 504 is reverse biased. For example, the reverse bias across the shaded cell 504 may be dissipated through the bypass diodes 532 as the bypass diodes 532 have a lower electrical resistance characteristic under reverse bias than the bulk of the shaded cell 504.

The presence of built-in bypass diodes 532 may be determined by comparing the electrical output of the device 500 before and after shading an individual cell 504. For example, the device 500 may be illuminated and the electrical potential generated by the device 500 is measured. One or more cells 504 may be shaded from the light while the remaining cells 504 are illuminated. The device 500 may be short circuited by joining the leads 506, 508 together. The device 500 may then be exposed to light for a predetermined time period, such as one hour. Both the shaded cells 504 and the unshaded cells 504 are then once again illuminated and the electrical potential generated by the device 500 is measured. If the electrical potential before and after the shading of the cells 504 is within approximately 100 millivolts of one another, then the device 500 may include built-in bypass diodes 532. Alternatively, if the electrical potential after the shading of the cells 504 is approximately 200 to 1500 millivolts lower than the electrical potential prior to the shading of the cells 504, then the device 500 likely does not include the built-in bypass diodes 532. In another embodiment, the presence of a built-in bypass diode 532 for a particular cell 504 may be determined by electrically probing the cell 504. If the cell 504 demonstrates a reversible, non-permanent diode breakdown when the cell 504 is reverse biased without illumination, then the cell 504 includes the built-in bypass diode 532. For example, if the cell 504 demonstrates greater than approximately 10 milliamps per square centimeter of leakage current when a reverse bias of approximately −5 to −8 volts is applied across the upper and lower electrode layers 514, 518 of the cell 504 without illumination, then the cell 504 includes the built-in bypass diode 532.

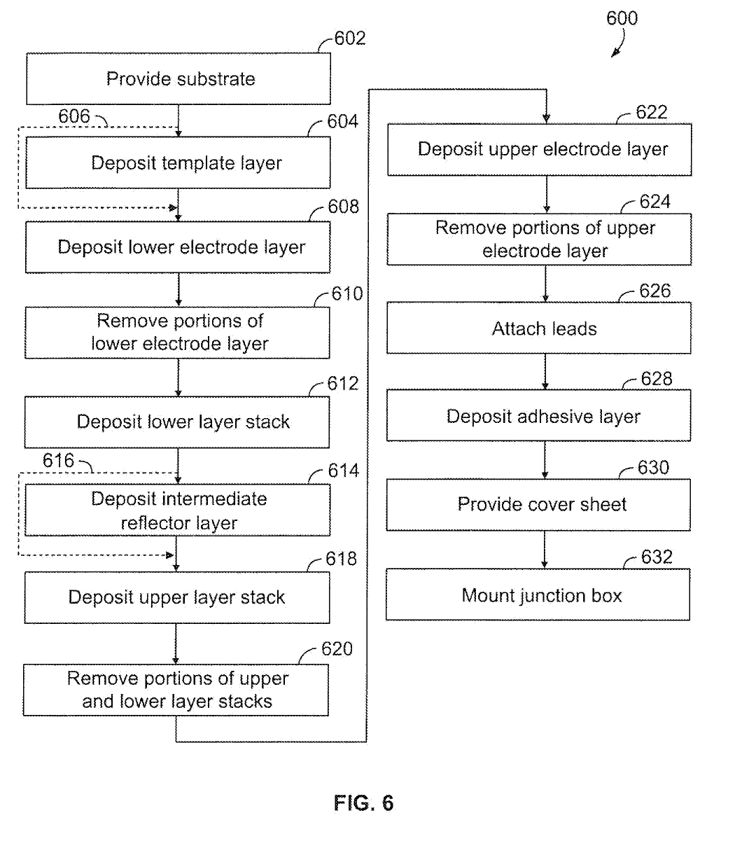

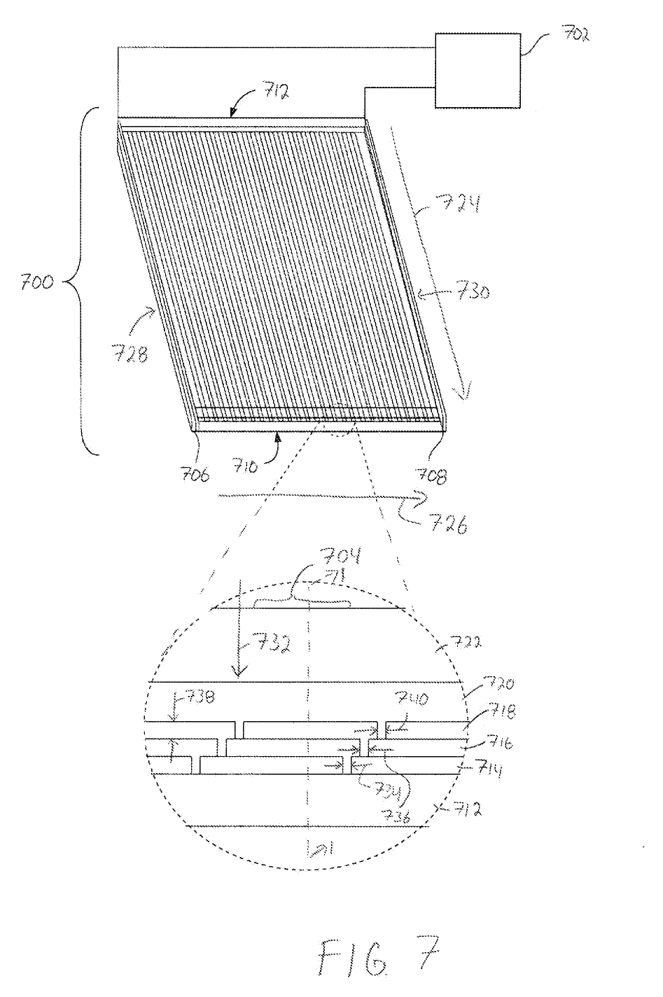

FIG. 6 is a flowchart of a process 600 for manufacturing a photovoltaic device in accordance with one embodiment. At 602, a substrate is provided. For example, a substrate such as the substrate 102 (shown in FIG. 1) may be provided. At 604, a template layer is deposited onto the substrate. For example, the template layer 114 (shown in FIG. 1) may be deposited onto the substrate 102. Alternatively, flow of the process 600 may bypass 604 along a path 606 such that no template layer is included in the photovoltaic device. At 608, a lower electrode layer is deposited onto the template layer or the substrate. For example, the lower electrode layer 112 (shown in FIG. 1) may be deposited onto the template layer 114 or the substrate 102.

At 610, portions of the lower electrode layer are removed to separate the lower electrode layer of each cell in the device from one another. As described above, portions of the lower electrode layer may be removed using a focused beam of energy, such as a laser beam. At 612, a lower active silicon layer stack is deposited. For example, the lower layer stack 108 (shown in FIG. 1) may be deposited onto the lower electrode layer 112 (shown in FIG. 1). At 614, an intermediate reflector layer is deposited above the lower layer stack. For example, the intermediate reflector layer 128 (shown in FIG. 1) may be deposited onto the lower layer stack 106. Alternatively, flow of the process 600 bypasses deposition of the intermediate reflector layer at 614 along path 616. At 618, an upper active silicon layer stack is deposited above the intermediate reflector layer or the lower layer stack. For example, in one embodiment, the upper layer stack 106 (shown in FIG. 1) is deposited onto the intermediate reflector layer 128. Alternatively, the upper layer stack 106 may be deposited onto the lower layer stack 108.

At 620, portions of the upper and lower layer stacks are removed between adjacent cells in the device. For example, sections of the upper and lower layer stacks 106, 108 (shown in FIG. 1) may be removed between adjacent cells 504 (shown in FIG. 5), as described above. At 622, an upper electrode layer is deposited above the upper and lower layer stacks. For example, the upper electrode layer 110 (shown in FIG. 1) may be deposited above the upper and lower layer stacks 106, 108. At 624, portions of the upper electrode layer are removed. For example, portions of the upper electrode layer 110 are removed to separate the upper electrode layers 110 of adjacent cells 504 in the device 500 (shown in FIG. 5) from one another. As described above, removal of portions of the upper electrode layer 110 may result in built-in bypass diodes in being formed in the upper layer stack 106.

At 626, conductive leads are electrically joined to the outermost cells in the device. For example, the leads 506, 508 (shown in FIG. 5) may be electrically coupled with the outermost cells 504 (shown in FIG. 5) in the device 500 (shown in FIG. 5). At 628, an adhesive layer is deposited above the upper electrode layer. For example, the adhesive layer 136 (shown in FIG. 1) may be deposited above the upper electrode layer 110 (shown in FIG. 1). At 630, a cover layer is affixed to the adhesive layer. For example, the cover layer 104 (shown in FIG. 1) may be joined to the underlying layers and components of the cell 100 (shown in FIG. 1) by the adhesive layer 136. At 632, a junction box is mounted to the device. For example, a junction box that is configured to deliver electric potential and/or current from the device 500 to one or more connectors may be mounted to and electrically coupled with the device 500.

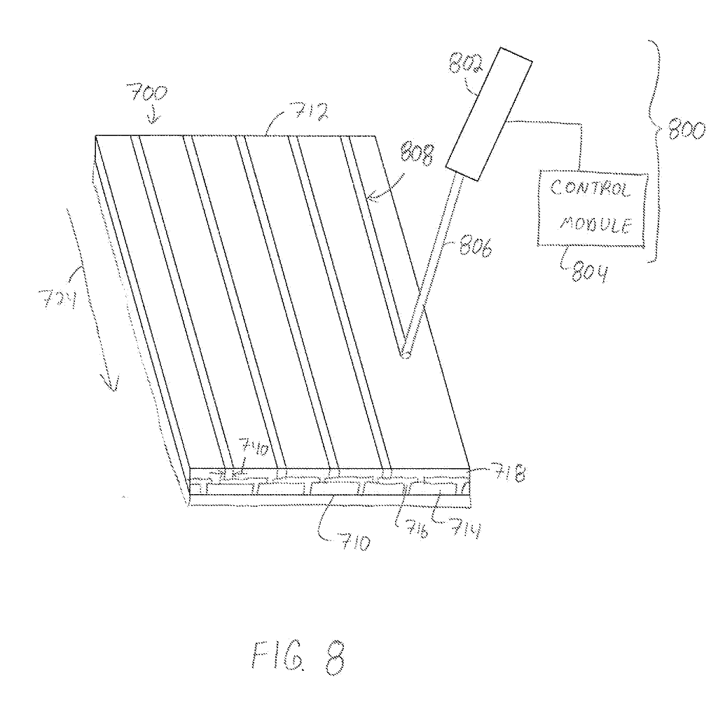

FIG. 7 is a schematic diagram of a photovoltaic device 700 and a magnified view 702 of the device 700 according to another embodiment. The device 700 includes a plurality of photovoltaic cells 704 electrically coupled in series with one another. The cells 704 may be similar to the cells 100 and/or the cells 504 (shown in FIGS. 1 and 5). For example, each of the cells 704 may have a tandem arrangement of upper and lower layer stacks 106, 108 (shown in FIG. 1) of active semiconductor layers or junctions that each absorb a different subset of the spectrum of wavelengths of light. Alternatively, each of the cells 704 may include a single semiconductor layer or junction that absorbs light. The schematic illustration shown in FIG. 1 may be a cross-sectional view along line 1-1 in FIG. 7.

The device 700 may include many cells 704 electrically coupled with one another in series. By way of example only, the device 700 may have twenty-five, fifty, or one hundred or more cells 704 connected with one another in a series. Each of the outermost cells 704 also may be electrically connected with one of a plurality of leads 706, 708. The leads 706, 708 may be similar to the leads 506, 508 (shown in FIG. 5) and extend in directions that are parallel to a length direction 724 of the device 700 between opposite ends 710, 712 of the device 700. The leads 706, 708 are separated from each other along a width direction 726 of the device 700 such that the leads 706, 708 extend along opposite sides 728, 730 of the device 700. The leads 706, 708 are connected with an external electrical load 702. The electric current generated by the device 500 is applied to the external load 542.

The cells 704 include several layers stacked on or above each other along a deposition direction 732 of the photovoltaic device 700. The deposition direction 732 may represent the direction in which the various layers or components of the photovoltaic device 700 are deposited and/or the direction in which light is received into the photovoltaic device 700. In the illustrated embodiment, these layers include a substrate 712, a lower electrode layer 714, a semiconductor layer 716, an upper electrode layer 718, an adhesive layer 720, and a cover layer 722. The substrate 712 may be similar to the substrate 102 (shown in FIG. 1) and/or the substrate 512 (shown in FIG. 5). The lower electrode layer 714 may be similar to the lower electrode layer 112 (shown in FIG. 1) and/or the lower electrode layer 514 (shown in FIG. 5). The semiconductor layer 716 may be similar to the tandem silicon layer stack 516 (shown in FIG. 5). Alternatively, the semiconductor layer 716 may include a different number of layers or junctions than the layer stack 516, and/or be formed from a different semiconductor material than the layer stack 516. The upper electrode layer 718 may be similar to the upper electrode layer 110 (shown in FIG. 1) and/or the upper electrode layer 518 (shown in FIG. 5). The adhesive layer 720 may be similar to the adhesive layer 136 (shown in FIG. 1) and/or the adhesive layer 520 (shown in FIG. 5). The cover layer 722 may be similar to the cover layer 104 (shown in FIG. 1) and/or the cover layer 522 (shown in FIG. 5).

Similar to the device 500 (shown in FIG. 5), the device 700 may be a monolithically integrated solar module similar to one or more of the embodiments described in the '510 Application. For example, in order to create the shapes of the lower and upper electrode layers 714, 718 and the semiconductor layer 716, the device 700 may be fabricated as a monolithically integrated module as described in the '510 Application. In one embodiment, portions of the lower electrode layer 714 are removed to create lower separation gaps 734 in the lower electrode layer 714. The portions of the lower electrode layer 714 may be removed using a patterning technique on the lower electrode layer 714. The lower separation gaps 724 can divide the lower electrode layer 714 into sections that are electrically separate or isolated from each other, with each section of the lower electrode layer 714 being present in a different cell 704. For example, a laser light may be used to create the lower separation gaps 724. In the illustrated embodiment, after removing portions of the lower electrode layer 714 to create the lower separation gaps 724, the remaining sections of the lower electrode layer 714 are arranged as linear strips extending in directions that are parallel to the length direction 724.

The semiconductor layer 716 is deposited above the lower electrode layer 714 such that the semiconductor layer 716 fills in the volumes in the lower separation gaps 724, as shown in FIG. 7. The semiconductor layer stack 716 may then be scribed or etched to create inter-layer separation gaps 736. The inter-layer separation gaps 736 can be formed by exposing the semiconductor layer stack 716 to a focused beam of energy, such as a laser light. The laser light may have a wavelength that is absorbed by the semiconductor layer stack 716 more than one or more other layers or components of the photovoltaic device 716. For example, the laser light may have a wavelength of 355 or 1064 nanometers.

The laser light removes portions of the semiconductor layer stack 716 to divide the semiconductor layer stack 716 into sections that are separate from each other, with each section of the semiconductor layer stack 716 being present in a different cell 704. In the illustrated embodiment, after removing portions of the semiconductor layer stack 716 to create the inter-layer separation gaps 736, the remaining sections of the semiconductor layer stack 716 are arranged in linear strips that extend in directions that are parallel to the length direction 724.

The upper electrode layer 718 is deposited above the semiconductor layer 716 and on the lower electrode layer 714 in the inter-layer gaps 736. In one embodiment, a thickness dimension 738 of the upper electrode layer 718 is based on one or more wavelengths of incident light that is received by the device 700. For example, the thickness dimension 738 of the upper electrode layer 718 that is measured in a direction parallel to the deposition direction 732 may be based on the wavelengths of light that are to be absorbed by the semiconductor layer 716. In one embodiment, the semiconductor layer 716 may include one or more films having one or more energy band gaps that absorb wavelengths of incident light. As a result, the thickness dimension 738 may be based on the band gap(s) of the semiconductor layer 716.

The upper electrode layer 718 may be deposited above the semiconductor layer 716 such that the upper electrode layer 718 fills in the volumes in the inter-layer separation gaps 736, as shown in FIG. 7. The upper electrode layer 718 can then be scribed or etched to create upper separation gaps 740. The upper separation gaps 740 can be formed by exposing the upper electrode layer 718 to a focused beam of energy, such as a laser light. The laser light removes portions of the upper electrode layer 718 to divide the upper electrode layer 718 into sections that are separate from each other, with each section of the upper electrode layer 718 being present in a different cell 704. In the illustrated embodiment, after removing portions of the upper electrode layer 718 to create the upper separation gaps 740, the remaining sections of the upper electrode layer 718 are arranged in linear strips that extend in directions that are parallel to the length direction 724. The adhesive and cover layers 720, 722 may then be provided above the upper electrode layer 718, as shown in FIG. 7.

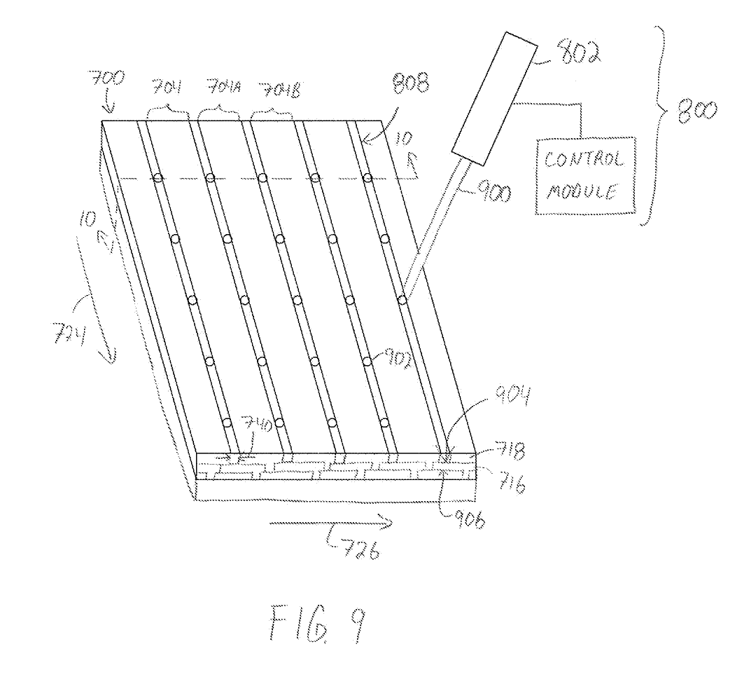

FIG. 8 is a perspective view of a scribing system 800 for creating one or more of the separation gaps 734, 736, 740 (shown in FIG. 7) in the photovoltaic device 700 in accordance with one embodiment. The scribing system 800 includes an energy source 802 and a control module 804. The energy source 802 provides a focused beam of energy 806 to remove portions of one or more of the lower electrode layer 714, the semiconductor layer 716, and/or the upper electrode layer 718. In one embodiment, the energy source 802 is a laser light source that emits a laser beam toward the photovoltaic device 700 as the focused beam of energy 806. The control module 804 is a device capable of controlling the energy source 802. For example, the control module 804 may be a computer processor-based device that receives input from an operator to turn the energy source 802 on or off and/or causes at least one of the energy source 820 or the photovoltaic device 700 to move relative to the other.

In FIG. 8, the scribing system 800 is shown removing portions of the upper electrode layer 718 to create the upper separation gaps 740. In order to create the upper separation gaps 740, the energy source 802 emits the focused beam of energy 806 and at least one of the energy source 802 or the photovoltaic device 700 moves relative to each other. For example, a conveyor or other device may move the photovoltaic device 700 relative to the energy source 802. The energy source 802 may continuously emit the focused beam of energy 806 as the photovoltaic device 700 and/or energy source 802 move relative to each other. The movement of the energy source 802 and/or the photovoltaic device 700 while the energy source 802 emits the beam of energy 804 can form a continuous scribe line 808 in the upper electrode layer 718. The scribe lines 808 form the upper separation gaps 740 shown in FIGS. 7 and 8.

The scribe lines 808 are referred to as “continuous” because, in one embodiment, the scribe lines 808 are elongated along at least one direction. For example, the scribe lines 808 may extend from the back side 712 of the photovoltaic device to the front side 710 of the photovoltaic device 700 in directions that are generally parallel to the length direction 724. Alternatively, the continuous scribe lines 808 may be elongated and extend a smaller distance between the sides 710, 712 and/or along different directions. In another embodiment, the scribe lines 808 may be non-continuous. For example, the scribe lines 808 may not extend from one side 710 to the other side 712 or may not be elongated in one direction more than one or more other directions.

FIG. 9 is a perspective view of the scribing system 800 in accordance with one embodiment. As described above, the scribing system 800 is shown in FIG. 8 as creating continuous scribe lines 808 that form the upper separation gaps 740 in the upper electrode layer 718. The scribing system 800 is shown in FIG. 9 as emitting a focused beam of energy 900, such as a laser light, to create discrete scribe marks 902. Similar to the scribe lines 808, the scribe marks 902 are formed when the energy source 802 directs the beam of energy 900 toward the photovoltaic device 700. The wavelength or energy of the focused beams of energy 806, 900 (shown in FIGS. 8 and 9) that are used to form the continuous scribe lines 808 and the discrete scribe marks 902 may be the same or differ from each other.

In FIG. 9, the scribing system 800 is shown exposing discrete and separate areas of the photovoltaic device 700 to create the discrete scribe marks 902. For example, the energy source 802 may direct the beam of energy 900 toward the photovoltaic device 700 without the energy source 802 and/or the photovoltaic device 700 moving relative to each other. The energy source 802 directs the beam of energy 900 to locations within the scribe line 808. For example, the beam of energy 806 (shown in FIG. 8) may remove the upper electrode layer 718 within the scribe line 808 and expose linear strips of the semiconductor layer 716 within the scribe lines 808. The scribing system 800 can then direct the beam of energy 900 toward one or more locations to form the scribe marks 902. In one embodiment, the energy source 802 directs the beam of energy 900 toward the photovoltaic device 700 to form a first scribe mark 902, then one or more of the energy source 802 or the photovoltaic device 700 moves relative to the other, the energy source 802 directs the beam of energy 900 toward the photovoltaic device 700 to form a second scribe mark 902, and so on, to form the scribe marks 902 shown in FIG. 9.

The scribe marks 902 are referred to as “discrete” because, in one embodiment, the scribe marks 902 are separated from each other in directions that are parallel to the length direction 724. For example, in contrast to the scribe lines 808, which are continuous and elongated along the length direction 724, the scribe marks 902 are not continuous or elongated along the length direction 724 and are separated from each other along the length direction 724. In another example, the scribe lines 808 are separated from each other along directions that are parallel to the width direction 726 and are elongated along the length direction 724 while the scribe marks 902 are separated from each other along both the perpendicular length and width directions 724, 726.

In the illustrated embodiment, the scribe lines 808 are continuous in that the scribe lines 808 define outer edges of neighboring photovoltaic cells 704. For example, the scribe lines 808 are disposed between photovoltaic cells 704, such as photovoltaic cells 704A and 704B, that are next to each other along the width direction 726 of the photovoltaic device 700. A single scribe line 808 separates neighboring photovoltaic cells 704 in one embodiment. Conversely, multiple scribe marks 902 may be disposed between neighboring photovoltaic cells 704. For example, in the illustrated embodiment, five scribe marks 902 are disposed between the photovoltaic cells 704A, 704B. Alternatively, multiple scribe lines 808 and/or a single scribe mark 902 may separate neighboring photovoltaic cells 704. The number of scribe lines 808 and scribe marks 902 shown in FIGS. 8 and 9 are provided as an illustrative example and is not intended to be limiting on all embodiments disclosed herein.

The beam of energy 900 increases a crystallinity of the semiconductor layer 716 at and/or near the scribe marks 902. The beam of energy 900 may locally increase the level, amount, percentage, or fraction of crystalline material in the semiconductor layer 716. For example, the beam of energy 900 may locally convert amorphous semiconductor material in the semiconductor layer 716 below the scribe mark 902 to poly-, micro-, or proto-crystalline material. The beam of energy 900 may increase the crystallinity of the semiconductor layer 716 by heating the semiconductor layer 716 and thereby causing the crystallinity of the semiconductor material in the semiconductor layer 716 to increase. The crystallinity of the semiconductor layer 716 may be increased in a volume that generally extends from the scribe mark 902 at an exposed upper surface 904 of the semiconductor layer 716 to a lower interface 906 between the semiconductor layer 716 and a layer disposed below the semiconductor layer 716, such as the lower electrode layer 716.

The beam of energy 900 may cause diffusion of dopants within the semiconductor layer 716 in the volume that generally extends from the scribe mark 902 at the upper surface 904 to the lower interface 906. For example, the semiconductor layer 716 may include one or more NIP or PIN junctions or stacks of semiconductor films. The beam of energy 900 heats the NIP or PIN junctions and causes n-type and/or p-type dopants in the junctions to diffuse into the intrinsic layers or films of the junctions in one embodiment.

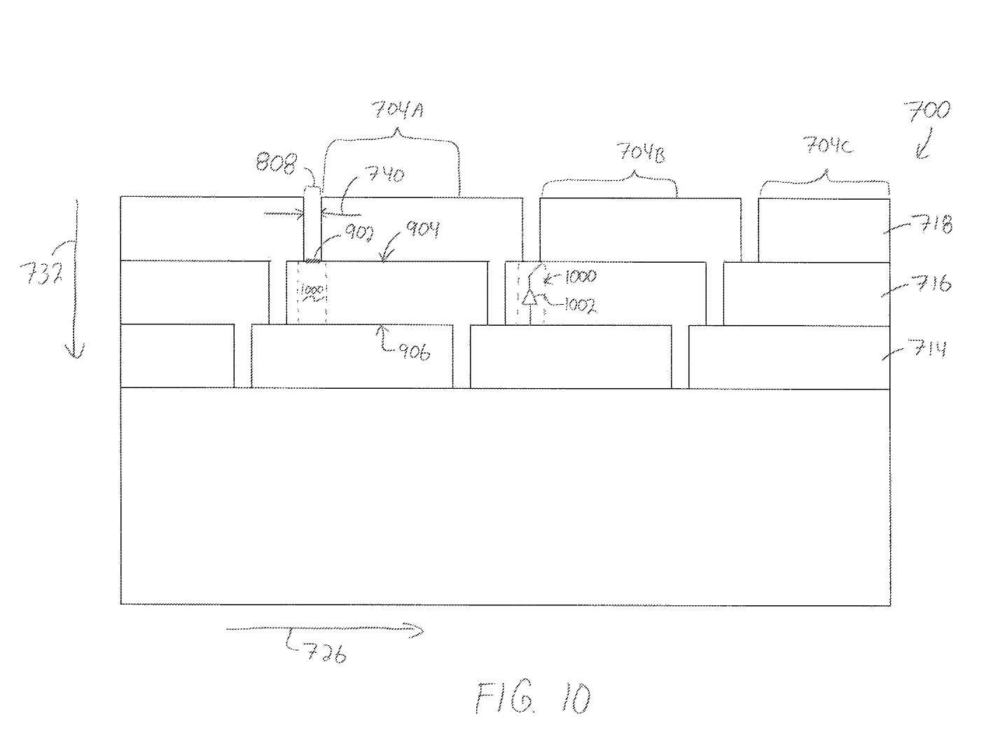

FIG. 10 is a cross-sectional view of the photovoltaic device 700 along line 10-10 shown in FIG. 9 in accordance with one embodiment. As described above, the focused beams of energy 900 (shown in FIG. 9) that are directed at the semiconductor layer 716 within the scribe lines 808 increase the crystallinity of the semiconductor layer 716 and/or the diffusion of dopants within the semiconductor layer 716. The increase in crystallinity and/or diffusion of dopants within the semiconductor layer 716 generally occurs in a localized region 1000 that extends from the scribe mark 902 at the upper surface 904 of the semiconductor layer 716 down to the lower interface 906 of the semiconductor layer 716 along the deposition direction 732. In the illustrated embodiment, the localized region 1000 is slightly wider than the scribe mark 902, the scribe line 808, and the upper separation gap 740 along at least the width direction 726 due to the increased heat of the semiconductor layer 716 in and around the localized region 1000. Conversely, the localized region 1000 may be the same width as or narrower than the scribe mark 902, the scribe line 808, and/or the upper separation gap 740.

The localized regions 1000 have greater amounts, fractions, or percentages of crystallinity than volumes of the semiconductor layer 716 disposed outside of the localized regions 1000. For example, the amount, fraction, or percentage of poly-, micro, or proto-crystalline material in the localized regions 1000 may be 5%, 10%, 15%, 20%, 25%, 35%, 50%, or 75% or more than the amount, fraction, or percentage of the same material in the volumes of the semiconductor layer 716 disposed outside of the localized regions 1000.

The diffusion of dopants within the localized regions 1000 of the semiconductor layer 716 may be greater than the diffusion of dopants within volumes of the semiconductor layer 716 disposed outside of the localized regions 1000. For example, the amount of n- and/or p-type dopants in the intrinsic layers of NIP and/or PIN junctions in the localized regions 1000 of the semiconductor layer 716 may be 10, 100, or 1000 or more times greater than the amount of n- and/or p-type dopants in the intrinsic layers of NIP and/or PIN junctions in volumes of the semiconductor layer 716 that are outside of the localized regions 1000.

The crystallinity of the localized regions 1000 may be determined by a variety of methods. For example, Raman spectroscopy can be used to obtain a comparison of the relative volume of noncrystalline material to crystalline material in samples of the localized regions 1000 and the volumes of the semiconductor layer 716 that are outside of the localized regions 1000. In one embodiment, laser light is directed into a volume of the semiconductor layer 716 that is outside the localized regions 1000 and another laser light of the same or similar wavelength is directed into the localized region 1000. The laser lights may have less energy than the focused beams of energy 806, 900 (shown in FIGS. 8 and 9) such that the laser lights do not significantly increase the crystallinity of the semiconductor layer 716 or the localized region 1000.

Based on the chemical content and crystal structure of the volumes outside of the localized regions 1000 and within the localized regions 1000, the monochromatic laser light may be scattered. As the laser light is scattered, the frequency (and wavelength) of the laser light changes. For example, the frequency of the scattered light can shift. The frequency of the scattered light is measured and analyzed. Based on the intensity and/or shift in the frequency of the scattered light, the relative volumes of amorphous and crystalline material of the semiconductor layer 716 outside of the localized regions 1000 and inside the localized regions 1000 may be determined. Based on these relative volumes of amorphous and crystalline material, the crystalline fraction or percentage of the semiconductor layer 716 and the localized regions 1000 may be measured.

In another example, one or more TEM images can be obtained of samples of the localized regions 1000 and samples of the semiconductor layer 716 outside of the localized regions 1000 to determine the crystalline fraction of the semiconductor layer 716 and the localized regions 1000. For example, one or more slices of the semiconductor layer 716 and the localized regions 1000 being examined may be obtained and TEM images may be obtained of the samples. The percentage of surface area in each TEM image that represents crystalline material is measured for each TEM image. The percentages of crystalline material in the TEM images can then be averaged to determine the crystalline fraction or percentage in the semiconductor layer 716 and the localized regions 1000.

The increased crystallinity and/or diffusion of dopants within the localized regions 1000 of the semiconductor layer 716 forms built-in bypass diodes 1002 in the semiconductor layer 716. The bypass diode 1002 is schematically shown in one of the localized regions 1000 of the semiconductor layer 716 in FIG. 10. The bypass diode 1002 extends between and is electrically coupled with the upper and lower electrode layers 718, 714 of neighboring photovoltaic cells 704.

Without the built-in bypass diodes 1002 between neighboring photovoltaic cells 704, a shaded photovoltaic cell 704 that is disposed between and electrically coupled in series with illuminated photovoltaic cells 704 may become reverse biased by the electric potential generated by the illuminated cells 704. For example, in FIG. 10, the schematically illustrated bypass diode 1002 is disposed in the photovoltaic cell 704B. The bypass diode 1002 extends between, and is coupled with, the lower electrode layer 714 and the upper electrode layer 718 of the photovoltaic cell 704B. The bypass diode 1002 provides a pathway for electric current to flow in order to bypass the photovoltaic cell 704B when the photovoltaic cell 704B is reverse biased. For example, the bypass diode 1002 provides a pathway for the electric current to flow from the neighboring photovoltaic cell 704A to the other neighboring photovoltaic cell 704C that does not extend through the semiconductor layer 716 of the photovoltaic cell 704B.

In operation, if the photovoltaic cell 704B is shaded while the photovoltaic cells 704A, 704C are illuminated, a reverse bias can develop across the photovoltaic cell 704B. For example, the lower electrode layer 714 of the photovoltaic cell 704B is electrically coupled with the upper electrode layer 718 of the photovoltaic cell 704A and the upper electrode layer 718 of the photovoltaic cell 704B is electrically coupled with the lower electrode layer 714 of the photovoltaic cell 704C. As a result, the current that is generated in the photovoltaic cells 704A, 704C creates a reverse bias voltage between the upper and lower electrode layers 718, 714 of the photovoltaic cell 704B. The bypass diode 1002 has a breakdown voltage that, when the reverse bias across the bypass diode 1002 exceeds the breakdown voltage, the bypass diode 1002 becomes conductive and allows the reverse bias to flow through the bypass diode 1002. The bypass diode 1002 permits current to flow through the localized region 1000 at a lower reverse bias voltage than the volumes of the semiconductor layer 716 located outside of the localized region 1000. For example, the increased crystallinity and/or interdiffusion of dopants in the localized region 1000 provides a path having a lower electrical resistance characteristic under reverse bias than the semiconductor layer 716 outside of the localized region 1000 within the photovoltaic cell 704.

In one example, if the reverse bias across the bypass diode 1002 exceeds the breakdown voltage of the bypass diode 1002, then electric current may flow through the bypass diode 1002 from the lower electrode layer 714 to the upper electrode layer 716 (or vice-versa) within the photovoltaic cell 704B. As a result, the photovoltaic cell 704B allows the reverse bias caused by the illuminated photovoltaic cells 704A, 704C to bypass the semiconductor layer 716 of the photovoltaic cell 704B and flow between the upper and lower electrode layers 718, 714 of the photovoltaic cell 704B. The photovoltaic cell 704B thereby can be protected from incinerating or being otherwise damaged by the reverse bias. Moreover, as a shaded photovoltaic cell may otherwise block electric current generated in a photovoltaic device from being extracted from the device, the bypass diodes 1002 may permit the photovoltaic device 700 to continue generating electric current to power the external load 702 (shown in FIG. 7) when one or more photovoltaic cells 704 are shaded while other photovoltaic cells 704 are illuminated.

The presence of the bypass diodes 1002 and/or localized regions 1000 may be determined by comparing the electrical output of the photovoltaic device 700 before and after shading an individual photovoltaic cell 704. For example, the photovoltaic device 700 may be illuminated and the current generated by the photovoltaic device 700 is measured (referred to as the “pre-shading current”). Then, one or more of the photovoltaic cells 704 may be shaded from the light while the remaining photovoltaic cells 704 are illuminated. The photovoltaic device 700 may then be short-circuited by electrically coupling the leads 706, 708 (shown in FIG. 7) with each other. The photovoltaic device 700 is then exposed to light for a predetermined time period, such as one hour. The photovoltaic cells 704 that were previously shaded, along with the other previously illuminated photovoltaic cells 704, are illuminated and the current generated by the photovoltaic device 700 is again measured (referred to as the “post-shading current”). If the pre- and post-shading currents are within a predetermined threshold of each another, such as 100 millivolts, then the photovoltaic device 700 may include one or more built-in bypass diodes 1002 and/or localized regions 1000. Conversely, if the pre- and post-shading currents are not within the predetermined threshold of each other, then the photovoltaic device 700 may not include the bypass diodes 1002 and/or localized regions 1000. Alternatively, the predetermined threshold may be a different amount, such as 10 millivolts, 1000 millivolts, and the like. In another embodiment, if the post-shading current is approximately 200 to 1500 millivolts lower than the pre-shading current, then the photovoltaic device 700 may not include the bypass diodes 1002 and/or the localized regions 1000.

The presence of the bypass diode 1002 in one or more of the photovoltaic cells 704 may be determined by electrically probing the photovoltaic cell 704. If the photovoltaic cell 704 demonstrates a reversible, non-permanent diode breakdown when the photovoltaic cell 704 is reverse biased without illumination, then the photovoltaic cell 704 may include the bypass diode 1002. For example, if the photovoltaic cell 704 demonstrates greater than approximately 10 milliamps per square centimeter of leakage current when a reverse bias of approximately −5 to −8 volts is applied across the upper and lower electrode layers 718, 714 of the photovoltaic cell 704 without illuminating the photovoltaic cell 704, then the photovoltaic cell 704 may include the bypass diode 1002 and/or localized region 1000.

In another embodiment, the localized regions 1000 in the semiconductor layer 716 may be formed by the focused beam of energy 806 (shown in FIG. 8) that also is used to form the scribe lines 808. For example, the focused beam of energy 806 that cuts the scribe lines 808 in the upper electrode layer 718 between neighboring photovoltaic cells 704 may be a picosecond laser that emits pulses of laser light toward the photovoltaic device 700 to provide the scribe lines 808. The picosecond laser pulses may sufficiently heat the volumes of the semiconductor layer 716 to form the localized regions 1000. The localized regions 1000 may include the volumes of the semiconductor layer 716 that disposed beneath the scribe lines 808 and between the upper surface 904 and the interface 906 of the semiconductor layer 716. Instead of being discrete localized regions 1000, the localized regions 1000 formed by the beams of energy 806 may be continuous and/or elongated similar to the scribe lines 808. Additional focused beams of energy, such as the beams of energy 900 (shown in FIG. 9), may be directed at the semiconductor layer 716 to further increase the crystallinity and/or interdiffusion of dopants within the localized regions 1000.

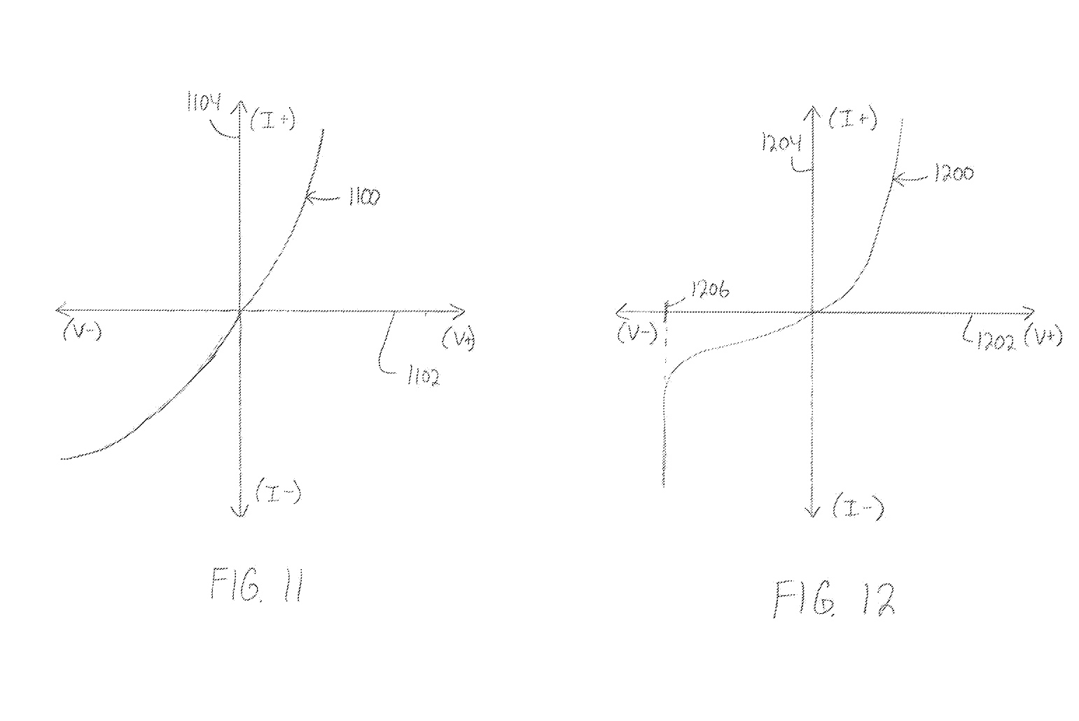

FIG. 11 illustrates an I-V curve 1100 of the bypass diode 1002 (shown in FIG. 10) formed after exposure of the semiconductor layer 716 (shown in FIG. 7) to the initial focused beam of energy 806 (shown in FIG. 8) in accordance with one embodiment. The I-V curve 1100 is shown alongside a horizontal axis 1102 representative of the voltage or bias applied across the bypass diode 1002 and a vertical axis 1104 representative of the current that flows through the bypass diode 1002. The I-V curve 1100 represents the relationship between the current (I) that passes through the bypass diode 1002 at various voltages or biases (V) that are applied across the bypass diode 1002.

In one embodiment, the I-V curve 1100 represents the relationship between the current (I) flowing through the bypass diode 1002 (shown in FIG. 10) and the reverse bias (V) applied across the bypass diode 1002 by neighboring photovoltaic cells 704 (shown in FIG. 7) after the semiconductor layer 716 (shown in FIG. 7) has been exposed to the initial focused beam of energy 806 (shown in FIG. 8) but prior to exposing the semiconductor layer 716 to the subsequent focused beam of energy 900 (shown in FIG. 9). As shown in FIG. 11, the I-V curve 1100 does not exhibit a reverse breakdown voltage of the bypass diode 1002. For example, the I-V curve 1100 generally becomes more flat and approaches a parallel relationship with the horizontal axis 1102 as the reverse bias applied across the bypass diode 1002 becomes more and more negative. While the bypass diode 1002 may have a breakdown voltage at a relatively large reverse bias (V), the bypass diode 1002 and/or semiconductor layer 716 within the photovoltaic cell 716 may incinerate before the bypass diode 1002 reaches the breakdown voltage. For example, the reverse bias across the bypass diode 1002 may be too large and cause the bypass diode 1002 to heat up and incinerate before the breakdown voltage is reached. The bypass diode 1002 may have a relatively large breakdown voltage or no breakdown voltage because the crystallinity and/or dopant interdiffusion in the localized region 1000 (shown in FIG. 10) may be too low. As a result, the bypass diode 1002 formed by the initial focused beam of energy 900 may be incapable of permitting current to flow through the bypass diode 1002 to bypass the semiconductor layer 716 when a relatively large reverse bias is applied to the bypass diode 1002.

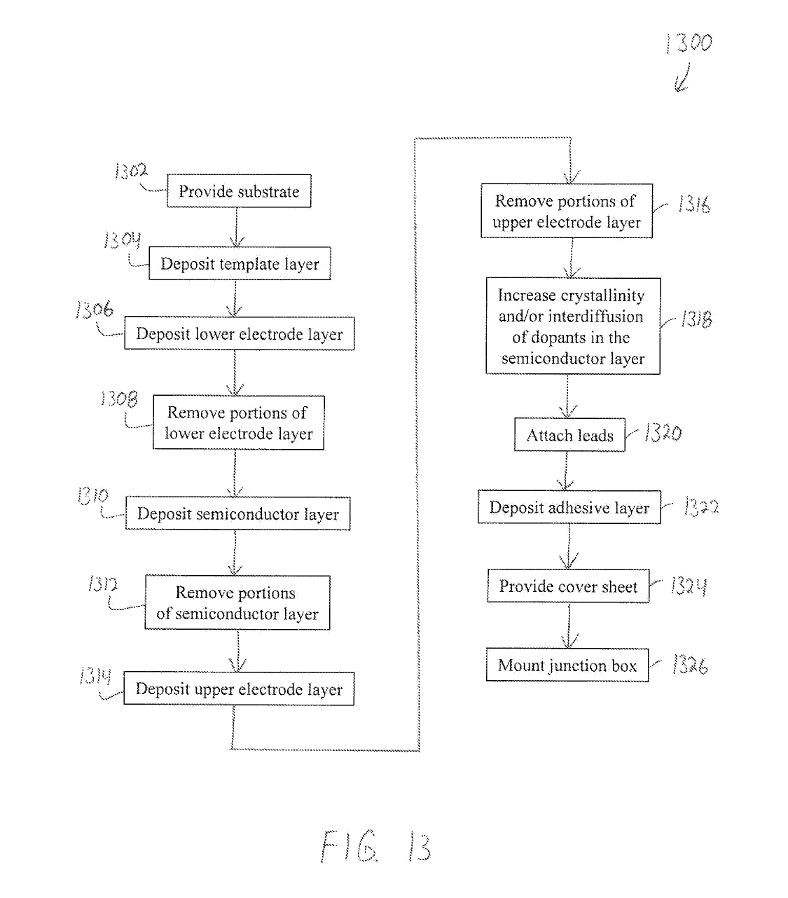

FIG. 12 illustrates an I-V curve 1200 of the bypass diode 1002 (shown in FIG. 10) formed after exposure of the semiconductor layer 716 (shown in FIG. 7) to the initial and subsequent focused beams of energy 806, 900 (shown in FIGS. 8 and 9) in accordance with one embodiment. Similar to the I-V curve 1100 (shown in FIG. 11), the I-V curve 1200 is shown alongside a horizontal axis 1202 representative of the voltage or bias applied across the bypass diode 1002 and a vertical axis 1204 representative of the current that flows through the bypass diode 1002.

In one embodiment, the I-V curve 1200 represents the relationship between the current (I) flowing through the bypass diode 1002 (shown in FIG. 10) and the reverse bias (V) applied across the bypass diode 1002 by neighboring photovoltaic cells 704 (shown in FIG. 7) after the semiconductor layer 716 (shown in FIG. 7) has been exposed to the initial and subsequent focused beams of energy 806, 900 (shown in FIGS. 8 and 9). As shown in FIG. 12, the I-V curve 1200 has a reverse breakdown voltage 1206. The reverse breakdown voltage 1206 represents the reverse bias that is applied across the bypass diode 1002 when the I-V curve 1200 becomes more vertical. For example, the current (I) that flows through the bypass diode 1002 increases by relatively large amounts for relatively small increases in the reverse bias (V). The current (I) that is able to flow through the bypass diode 1002 is able to increase significantly and bypass the semiconductor layer 716 of the photovoltaic cell 704 that includes the bypass diode 1002 when the reverse bias (V) across the bypass diode 1002 becomes more negative. After exposing the semiconductor layer 716 to the initial and subsequent beams of energy 806, 900, the bypass diode 1002 may have a smaller breakdown voltage 1206 that allows current to flow through the bypass diode 1002 to bypass the semiconductor layer 716 when smaller reverse biases are applied to the bypass diode 1002. For example, the localized regions 1000 that include the bypass diodes 1002 may have smaller breakdown voltages 1206 than volumes of the semiconductor layer 716 that are disposed outside of the localized regions 1000.

FIG. 13 is a flowchart of a process 1300 for manufacturing a photovoltaic device in accordance with one embodiment. The process 1300 may be used to provide one or more of the photovoltaic devices 100, 500, or 700 (shown in FIGS. 1, 5, and 7).

At 1302, a substrate is provided. For example, a substrate such as the substrate 102 (shown in FIG. 1), the substrate 512 (shown in FIG. 5), and/or the substrate 712 (shown in FIG. 7) may be provided.

At 1304, a template layer is deposited above the substrate. For example, the template layer 134 (shown in FIG. 1) may be deposited onto the substrate 102, 512, 712 (shown in FIGS. 1, 5, and 7). Alternatively, no template layer is provided.

At 1306, a lower electrode layer is deposited above the template layer or the substrate. For example, the lower electrode layer 132, 514, or 714 (shown in FIGS. 1, 5, and 7) may be deposited directly onto the template layer 134 (shown in FIG. 1), directly onto the substrate 102, 512, or 712 (shown in FIGS. 1, 5, and 7), or onto some other layer or film deposited onto the template layer 134 or substrate 102, 512, 712.

At 1308, portions of the lower electrode layer are removed. For example, scribe lines such as the scribe lines 808 (shown in FIG. 8) may be cut into the lower electrode layer 132, 514, or 714 (shown in FIGS. 1, 5, and 7). The scribe lines separate the lower electrode layer 132, 514, 714 into separate sections, with each section disposed in a different photovoltaic cell 100, 504, 704 (shown in FIGS. 1, 5, and 7). In one embodiment, the portions of the lower electrode layer 132, 514, 714 are removed by exposing the lower electrode layer 132, 512, 714 to a focused beam of energy, such as the beam of energy 806 (shown in FIG. 8) from the energy source 802 (shown in FIG. 8). Alternatively, the portions may be removed using a different process, such as a chemical etch.

At 1310, a semiconductor layer is deposited above the lower electrode layer. For example, one or more semiconductor layers or films may be deposited above the lower electrode layer 132, 514, 714 (shown in FIGS. 1, 5, and 7) to form the semiconductor layer stack 108 or 516 (shown in FIGS. 1 and 5) or to form the semiconductor layer 716 (shown in FIG. 7). As described above, the semiconductor layer that is deposited above the lower electrode layer 132, 514, 714 may include one or more NIP or PIN junctions stacked above or on top of each other, such as in a tandem arrangement described above.

At 1312, portions of the semiconductor layer are removed. For example, scribe lines such as the scribe lines 808 (shown in FIG. 8) may be cut into the semiconductor layer stack 108 or 516 (shown in FIGS. 1 and 5) or the semiconductor layer 716 (shown in FIG. 7). The scribe lines separate the semiconductor layer stack 108, 516 or the semiconductor layer 716 into separate sections, with each section disposed in a different photovoltaic cell 100, 504, 704 (shown in FIGS. 1, 5, and 7). In one embodiment, the portions of the semiconductor layer stack 108, 516 or the semiconductor layer 716 are removed by exposing the semiconductor layer stack 108, 516 or the semiconductor layer 716 to a focused beam of energy, such as the beam of energy 806 (shown in FIG. 8) from the energy source 802 (shown in FIG. 8). Alternatively, the portions may be removed using a different process, such as a chemical etch.

At 1314, an upper electrode layer is deposited above the semiconductor layer. For example, the upper electrode layer 130, 518, or 718 (shown in FIGS. 1, 5, and 7) may be deposited above the semiconductor layer that was deposited at 1312.

At 1316, portions of the upper electrode layer are removed. For example, scribe lines such as the scribe lines 808 (shown in FIG. 8) may be cut into the upper electrode layer 130, 518, or 718 (shown in FIGS. 1, 5, and 7). The scribe lines separate the upper electrode layer 130, 518, or 718 into separate sections, with each section disposed in a different photovoltaic cell 100, 504, 704 (shown in FIGS. 1, 5, and 7). In one embodiment, the portions of the upper electrode layer 130, 518, or 718 are removed by exposing the upper electrode layer 130, 518, or 718 to a focused beam of energy, such as the beam of energy 806 (shown in FIG. 8) from the energy source 802 (shown in FIG. 8). Alternatively, the portions may be removed using a different process, such as a chemical etch.

At 1318, the crystallinity and/or interdiffusion of dopants within the semiconductor layer deposited at 1310 are increased. The crystallinity and/or interdiffusion of dopants may be increased in discrete areas, such as the localized regions 1000 (shown in FIG. 10) of the semiconductor layer stack 108 or 516 (shown in FIGS. 1 and 5) or the semiconductor layer 716 (shown in FIG. 7). In one embodiment, the crystallinity and/or interdiffusion of dopants in the semiconductor layer stack 108 or 516 or the semiconductor layer 716 forms built-in bypass diodes, such as the bypass diodes 1002 (shown in FIG. 10).

At 1320, conductive leads are electrically joined to the outermost photovoltaic cells in the photovoltaic device. For example, the leads 506, 508 and/or the leads 706, 708 (shown in FIGS. 5 and 7) may be electrically coupled with the outermost photovoltaic cells 504, 704 (shown in FIGS. 5 and 7) along the sides 728, 730 (shown in FIG. 7) of the photovoltaic device 500 or 700 (shown in FIGS. 5 and 7). One of the leads 506, 508 or one of the leads 706, 708 can be joined with the upper electrode layer 518, 718 (shown in FIGS. 5 and 7) of one of the outermost photovoltaic cells 504, 704 while the other of the leads 506, 508 or the other of the leads 706, 708 is joined to the lower electrode layer 514, 714 (shown in FIGS. 5 and 7).

At 1322, an adhesive layer is deposited above the upper electrode layer. For example, the adhesive layer 136, 520, or 720 (shown in FIGS. 1, 5, and 7) may be deposited above the upper electrode layer 130, 514, or 714 (shown in FIGS. 1, 5, and 7).

At 1324, a cover layer is affixed to the adhesive layer. For example, the cover layer 104, 522, or 722 (shown in FIGS. 1, 5, and 7) may be joined to the adhesive layer 136, 520, or 720 (shown in FIGS. 1, 5, and 7). The cover layer may be light transmissive to permit incident light to enter into the photovoltaic device 100, 500, 700 (shown in FIGS. 1, 5, and 7).

At 1326, a junction box is mounted to the device. For example, a junction box that is configured to deliver electric potential and/or current from the photovoltaic device 100, 500, 700 (shown in FIGS. 1, 5, and 7) may be joined to the photovoltaic device 100, 500, 700 and electrically coupled with the leads 506, 508 and/or 706, 708 (shown in FIGS. 5 and 7). The junction box may be configured to receive or mate with connectors or cables that direct the current generated by the photovoltaic device 100, 500, 700 to the external load 542, 702 (shown in FIGS. 5 and 7).

In one embodiment, a photovoltaic device includes: a substrate; lower and upper electrode layers disposed above the substrate; and a semiconductor layer disposed between the lower and upper electrode layers, the semiconductor layer absorbing incident light to excite electrons from the semiconductor layer, wherein the semiconductor layer includes a built-in bypass diode extending between and coupled with the lower and upper electrode layers, the bypass diode permitting electric current to flow through the bypass diode when a reverse bias is applied across the lower and upper electrode layers.

In another aspect, the bypass diode extends from an upper surface of the semiconductor layer to an opposite interface of the semiconductor layer.

In another aspect, the bypass diode is disposed within the semiconductor layer between the upper and lower electrode layers.

In another aspect, a localized region of the semiconductor layer that includes the bypass diode has a greater crystallinity than volumes of the semiconductor layer that are outside of the localized region.

In another aspect, the bypass diode has a smaller breakdown voltage than other volumes of the semiconductor layer.

In another aspect, the bypass diode extends through the semiconductor layer from the lower electrode layer to a scribe line disposed above the semiconductor layer along a direction that light is received into the semiconductor layer and that separates the upper electrode layer into sections.

In another aspect, the bypass diode permits the electric current to flow through the bypass diode instead of through the semiconductor layer.

In another embodiment, a method for manufacturing a photovoltaic device includes: depositing a lower electrode layer above a substrate, a semiconductor layer above the lower electrode layer, and an upper electrode layer above the semiconductor layer, the semiconductor layer configured to absorb incident light to excite electrons from the semiconductor layer; and increasing at least one of a crystallinity or a diffusion of dopants in the semiconductor layer between the lower electrode layer and the upper electrode layer to form a built-in bypass diode, the bypass diode configured to permit electric current to flow through the bypass diode when a reverse bias is applied across the lower and upper electrode layers.

In another aspect, the increasing operation comprises exposing the semiconductor layer to a focused beam of energy.

In another aspect, the increasing operation comprises exposing the semiconductor layer to a focused beam of energy that also separates the upper electrode layer into separate sections.

In another aspect, the increasing operation comprises forming a scribe line in the upper electrode layer and directing a focused beam of energy into the semiconductor layer within the scribe line.

In another aspect, the scribe lines are formed as elongated lines that separate the upper electrode layer into sections and the focused beam of energy is directed at separate scribe marks on the semiconductor layer that are spaced apart from each other.

In another aspect, the increasing operation comprises exposing the semiconductor layer to a plurality of laser lights.

In another aspect, the increasing operation comprises exposing the semiconductor layer to an initial focused beam of energy that increases the at least one of the crystallinity or the diffusion of dopants in a localized region of the semiconductor layer and exposing the semiconductor layer to a subsequent focused beam of energy that further increases the at least one of the crystallinity or the diffusion of dopants in the localized region.

In another aspect, the increasing operation comprises forming the bypass diode in the semiconductor layer by exposing the semiconductor layer to a first focused beam of energy and reducing a reverse breakdown voltage of the bypass diode by exposing the semiconductor layer to a second focused beam of energy.

In another embodiment, a photovoltaic device includes: a substrate; and a plurality of electrically coupled photovoltaic cells disposed above the substrate in a direction that incident light is received by the photovoltaic cells, the photovoltaic cells generating electric current based on the light that is received by the photovoltaic cells, each of the photovoltaic cells including: lower and upper electrode layers disposed above the substrate; and a semiconductor layer disposed between the lower and upper electrode layers, the semiconductor layer absorbing the light to excite electrons from the semiconductor layer, wherein the semiconductor layer of at least one of the photovoltaic cells includes a built-in bypass diode extending between and coupled with the lower and upper electrode layers of the at least one of the photovoltaic cells, the bypass diode permitting the electric current to flow between neighboring ones of the photovoltaic cells through the bypass diode when the at least one of the photovoltaic cells is reverse biased.

In another aspect, the bypass diode is disposed within the semiconductor layer of the at least one of the photovoltaic cells between the upper and lower electrode layers.

In another aspect, a localized region of the semiconductor layer of the at least one of the photovoltaic cells that includes the bypass diode has a greater crystallinity than volumes of the semiconductor layer that are outside of the localized region.

In another aspect, the upper electrode layers of the photovoltaic cells are separated by a scribe line, the bypass diode extending from the scribe line to the lower electrode layer of the semiconductor layer in the at least one of the photovoltaic cells.

In another aspect, the bypass diode permits the electric current to flow through the bypass diode instead of through the semiconductor layer of the at least one of the photovoltaic cells.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the subject matter described herein without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the subject matter disclosed herein should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

What is claimed is:

1. A photovoltaic device comprising:
a substrate;
lower and upper electrode layers disposed above the substrate; and
a semiconductor layer disposed between the lower and upper electrode layers, the semiconductor layer absorbing incident light to excite electrons from the semiconductor layer, wherein the semiconductor layer includes a built-in bypass diode extending between and coupled with the lower and upper electrode layers, the bypass diode permitting electric current to flow through the bypass diode when a reverse bias is applied across the lower and upper electrode layers.

2. The photovoltaic device of claim 1, wherein the bypass diode extends from an upper surface of the semiconductor layer to an opposite interface of the semiconductor layer.

3. The photovoltaic device of claim 1, wherein the bypass diode is disposed within the semiconductor layer between the upper and lower electrode layers.

4. The photovoltaic device of claim 1, wherein a localized region of the semiconductor layer that includes the bypass diode has a greater crystallinity than volumes of the semiconductor layer that are outside of the localized region.

5. The photovoltaic device of claim 1, wherein the bypass diode has a smaller breakdown voltage than other volumes of the semiconductor layer.

6. The photovoltaic device of claim 1, wherein the bypass diode extends through the semiconductor layer from the lower electrode layer to a scribe line disposed above the semiconductor layer along a direction that light is received into the semiconductor layer and that separates the upper electrode layer into sections.

7. The photovoltaic device of claim 1, wherein the bypass diode permits the electric current to flow through the bypass diode instead of through the semiconductor layer.

8. A method for manufacturing a photovoltaic device, the method including:
depositing a lower electrode layer above a substrate, a semiconductor layer above the lower electrode layer, and an upper electrode layer above the semiconductor layer, the semiconductor layer configured to absorb incident light to excite electrons from the semiconductor layer; and
increasing at least one of a crystallinity or a diffusion of dopants in the semiconductor layer between the lower electrode layer and the upper electrode layer to form a built-in bypass diode, the bypass diode configured to permit electric current to flow through the bypass diode when a reverse bias is applied across the lower and upper electrode layers.

9. The method of claim 8, wherein the increasing operation comprises exposing the semiconductor layer to a focused beam of energy.

10. The method of claim 8, wherein the increasing operation comprises exposing the semiconductor layer to a focused beam of energy that also separates the upper electrode layer into separate sections.

11. The method of claim 8, wherein the increasing operation comprises forming a scribe line in the upper electrode layer and directing a focused beam of energy into the semiconductor layer within the scribe line.

12. The method of claim 11, wherein the scribe lines are formed as elongated lines that separate the upper electrode layer into sections and the focused beam of energy is directed at separate scribe marks on the semiconductor layer that are spaced apart from each other.

13. The method of claim 8, wherein the increasing operation comprises exposing the semiconductor layer to a plurality of laser lights.

14. The method of claim 8, wherein the increasing operation comprises exposing the semiconductor layer to an initial focused beam of energy that increases the at least one of the crystallinity or the diffusion of dopants in a localized region of the semiconductor layer and exposing the semiconductor layer to a subsequent focused beam of energy that further increases the at least one of the crystallinity or the diffusion of dopants in the localized region.

15. The method of claim 8, wherein the increasing operation comprises forming the bypass diode in the semiconductor layer by exposing the semiconductor layer to a first focused beam of energy and reducing a reverse breakdown voltage of the bypass diode by exposing the semiconductor layer to a second focused beam of energy.

16. A photovoltaic device comprising:
a substrate; and
a plurality of electrically coupled photovoltaic cells disposed above the substrate in a direction that incident light is received by the photovoltaic cells, the photovoltaic cells generating electric current based on the light that is received by the photovoltaic cells, each of the photovoltaic cells including:
lower and upper electrode layers disposed above the substrate; and
a semiconductor layer disposed between the lower and upper electrode layers, the semiconductor layer absorbing the light to excite electrons from the semiconductor layer,
wherein the semiconductor layer of at least one of the photovoltaic cells includes a built-in bypass diode extending between and coupled with the lower and upper electrode layers of the at least one of the photovoltaic cells, the bypass diode permitting the electric current to flow between neighboring ones of the photovoltaic cells through the bypass diode when the at least one of the photovoltaic cells is reverse biased.

17. The photovoltaic device of claim 16, wherein the bypass diode is disposed within the semiconductor layer of the at least one of the photovoltaic cells between the upper and lower electrode layers.

18. The photovoltaic device of claim 16, wherein a localized region of the semiconductor layer of the at least one of the photovoltaic cells that includes the bypass diode has a greater crystallinity than volumes of the semiconductor layer that are outside of the localized region.

19. The photovoltaic device of claim 16, wherein the upper electrode layers of the photovoltaic cells are separated by a scribe line, the bypass diode extending from the scribe line to the lower electrode layer of the semiconductor layer in the at least one of the photovoltaic cells.

20. The photovoltaic device of claim 16, wherein the bypass diode permits the electric current to flow through the bypass diode instead of through the semiconductor layer of the at least one of the photovoltaic cells.
